(19) United States
(12) Patent Application Publication
(10) Pub. No.: US 2026/0032944 A1
(43) Pub. Date: Jan. 29, 2026

(54) NANOSHEET DEVICES WITH OXIDE SACRIFICIAL LAYERS AND METHODS OF FABRICATING THE SAME

(71) Applicant: Taiwan Semiconductor Manufacturing Company, Ltd., Hsinchu (TW)

(72) Inventors: Tzu-Ging Lin, Hsinchu (TW); Yun-Chen Wu, Hsinchu (TW); Ryan Chia-Jen Chen, Hsinchu (TW)

(73) Assignee: Taiwan Semiconductor Manufacturing Company, Ltd., Hsinchu (TW)

(21) Appl. No.: 18/968,809

(22) Filed: Dec. 4, 2024

Related U.S. Application Data
(60) Provisional application No. 63/676,801, filed on Jul. 29, 2024.

(51) Int. Cl. H10D 30/00; H10D 30/67; H10D 64/01

(52) U.S. Cl. CPC H10D 30/509; H10D 64/015; H10D 30/502; H10D 30/6735

(57) ABSTRACT

A method includes forming a fin protruding from a substrate, where the fin includes semiconductor layers interleaved with dielectric sacrificial layers. The method includes forming inner spacers at end portions of each of the dielectric sacrificial layers. The method includes forming source/drain features in the fin adjacent to the inner spacers. The method includes removing a portion of the fin between adjacent source/drain features to form a trench. The method includes forming an isolation structure in the trench.

### CROSS-REFERENCE TO RELATED PATENT APPLICATIONS

This application claims priority to U.S. Provisional Application Ser. No. 63/676,801, filed Jul. 29, 2024, the entire disclosure of which is incorporated herein for all purposes.

### BACKGROUND

As the semiconductor industry has progressed into nanometer technology process nodes in pursuit of higher device density, higher performance, and lower costs, challenges from both fabrication and design issues have resulted in the development of multi-gate devices, such as fin field-effect transistors (FinFETs) and gate-all-around (GAA) transistors. To continue to provide the desired scaling and increased density for multi-gate devices in advanced technology nodes, reduction of the gate pitch is necessary. Various schemes, such as continuous poly on diffusion edge (CPODE) structures, have been used to scale the gate pitch while preventing leakage current between transistors. However, such schemes have not been entirely satisfactory in providing the level of device density, cell isolation, and device performance required for aggressively scaled circuits and devices. Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a three-dimensional perspective view of an example semiconductor device, in portion or in entirety, according to some embodiments of the present disclosure.

FIGS. 2A and 2B each illustrate a flow chart of an example method for fabricating an example semiconductor device, according to some embodiments of the present disclosure.

FIGS. 3A, 3B, and 3C each illustrate a cross-sectional view of an example semiconductor device, in portion or in entirety, according to some embodiments of the present disclosure.

FIGS. 4A, 4B, 5A, 5B, 11A, 11B, 14A, 14B, 15A, 15B, 16A, 16B, 18A, 18B, 22A, 22B, 26A, and 26B each illustrate a top view of an example semiconductor device, in portion or in entirety, during intermediate steps of the method of FIGS. 2A and/or 2B, according to some embodiments of the present disclosure.

FIGS. 4C, 5C, 11C, 14C, 15C, 16C, 18C, 22C, and 26C each illustrate a cross-sectional view of the example semiconductor device taken along line A-A′ of FIGS. 4A/4B, 5A/5B, 11A/11B, 14A/14B, 15A/15B, 16A/16B, 18A/18B, 22A/22B, and 26A/26B, respectively, in portion or in entirety, during intermediate steps of the method of FIGS. 2A and/or 2B, according to some embodiments of the present disclosure.

FIGS. 6A, 7A, 8A, 9A, and 10A each illustrate a cross-sectional view of the example semiconductor device taken along line A-A′ of FIGS. 5A/5B, in portion or in entirety, during intermediate steps of the method of FIGS. 2A and/or 2B, according to some embodiments of the present disclosure.

FIGS. 12A and 13A each illustrate a cross-sectional view of the example semiconductor device taken along line A-A′ of FIGS. 11A/11B, in portion or in entirety, during intermediate steps of the method of FIGS. 2A and/or 2B, according to some embodiments of the present disclosure.

FIG. 17A illustrates a cross-sectional view of the example semiconductor device taken along line A-A′ of FIGS. 16A/16B, in portion or in entirety, during intermediate steps of the method of FIGS. 2A and/or 2B, according to some embodiments of the present disclosure.

FIGS. 19A, 20, and 21A each illustrate a cross-sectional view of the example semiconductor device taken along line A-A′ of FIGS. 18A/18B, in portion or in entirety, during intermediate steps of the method of FIGS. 2A and/or 2B, according to some embodiments of the present disclosure.

FIGS. 23A, 24A, and 25A each illustrate a cross-sectional view of the example semiconductor device taken along line A-A′ of FIGS. 22A/22B, in portion or in entirety, during intermediate steps of the method of FIGS. 2A and/or 2B, according to some embodiments of the present disclosure.

FIG. 27A illustrates a cross-sectional view of the example semiconductor device taken along line A-A′ of FIGS. 26A/26B, in portion or in entirety, during intermediate steps of the method of FIGS. 2A and/or 2B, according to some embodiments of the present disclosure.

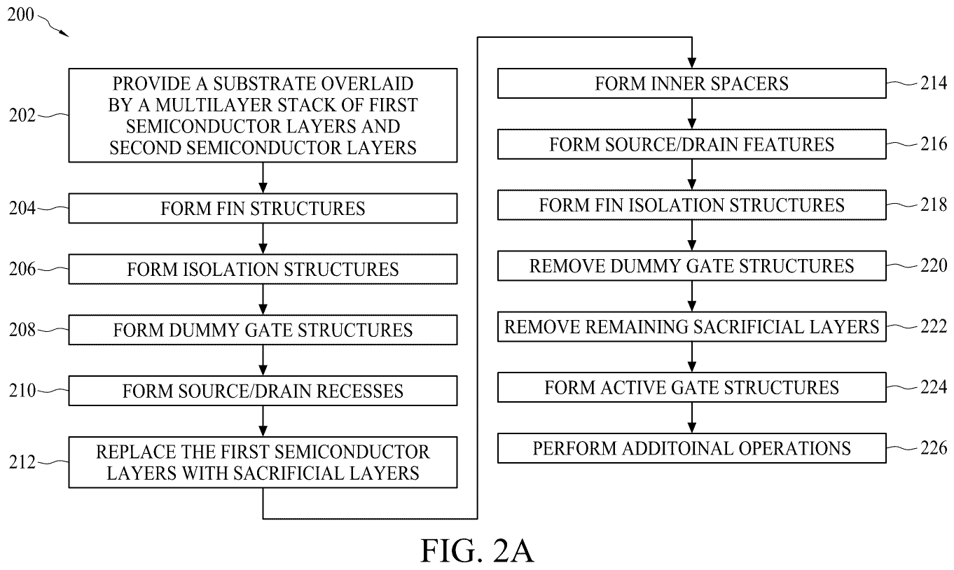

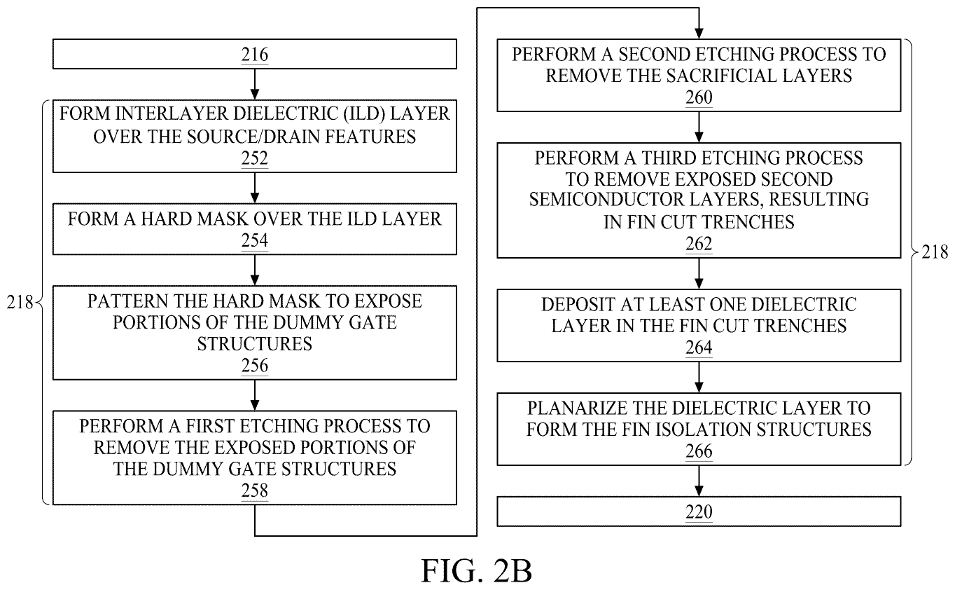

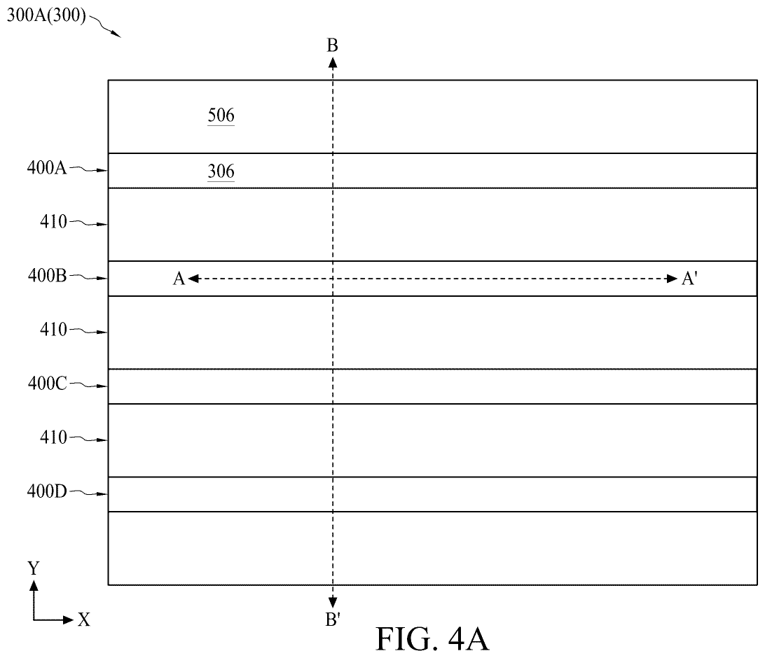

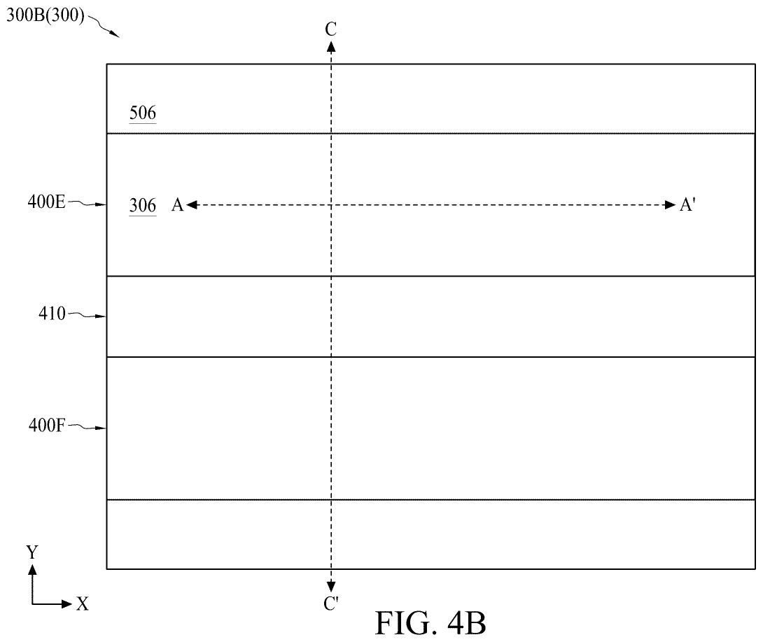

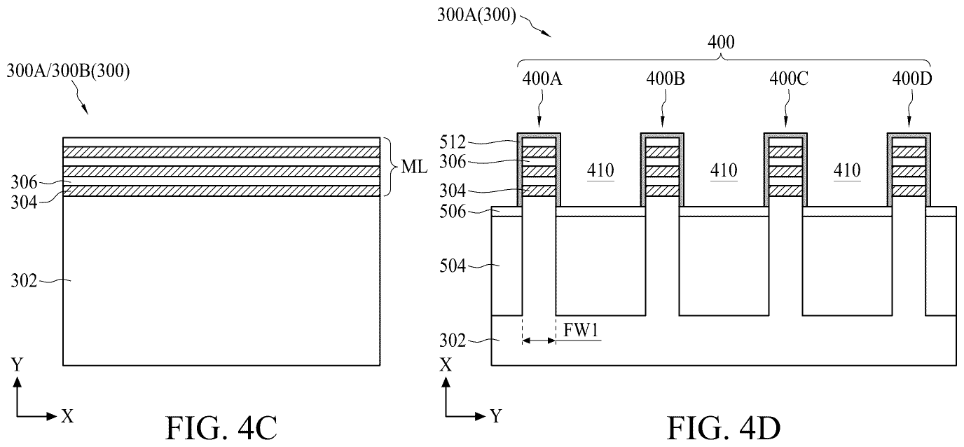

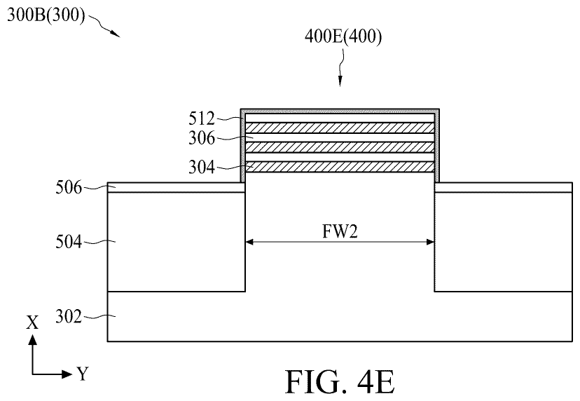

FIGS. 4D, 5D, 11D, 14D, 15D, 16D, 18D, 22D, and 26D each illustrate a cross-sectional view of the example semiconductor device taken along line B-B′ of FIGS. 4A, 5A, 11A, 14A, 15A, 16A, 18A, 22A, and 26A, respectively, in portion or in entirety, during intermediate steps of the method of FIGS. 2A and/or 2B, according to some embodiments of the present disclosure.

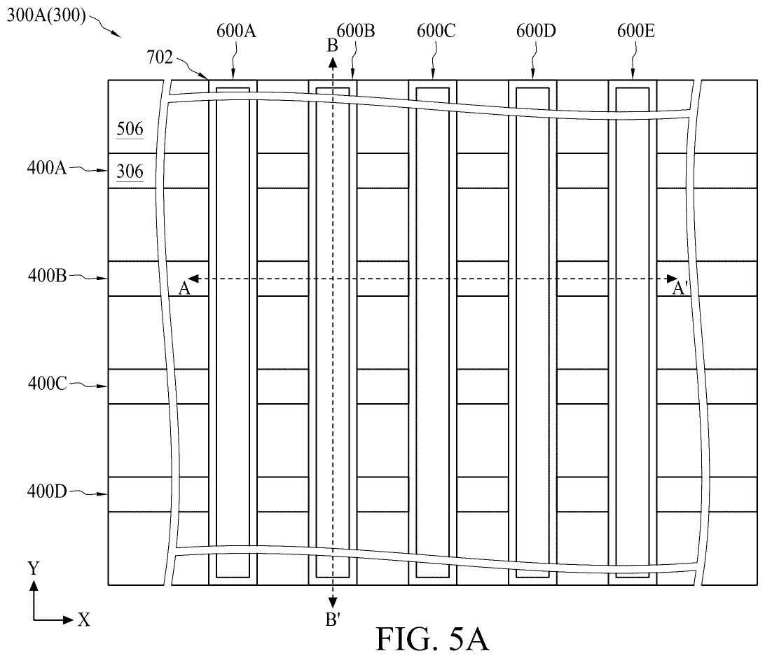

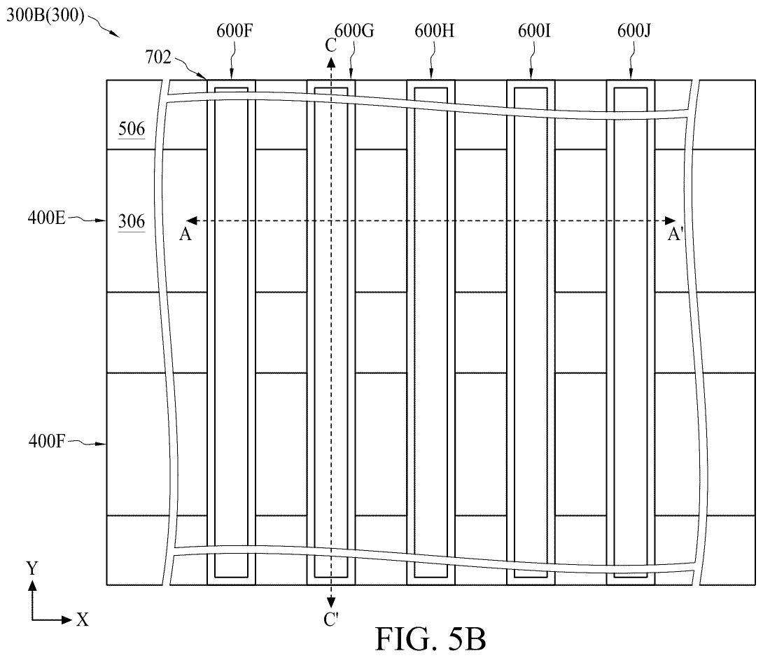

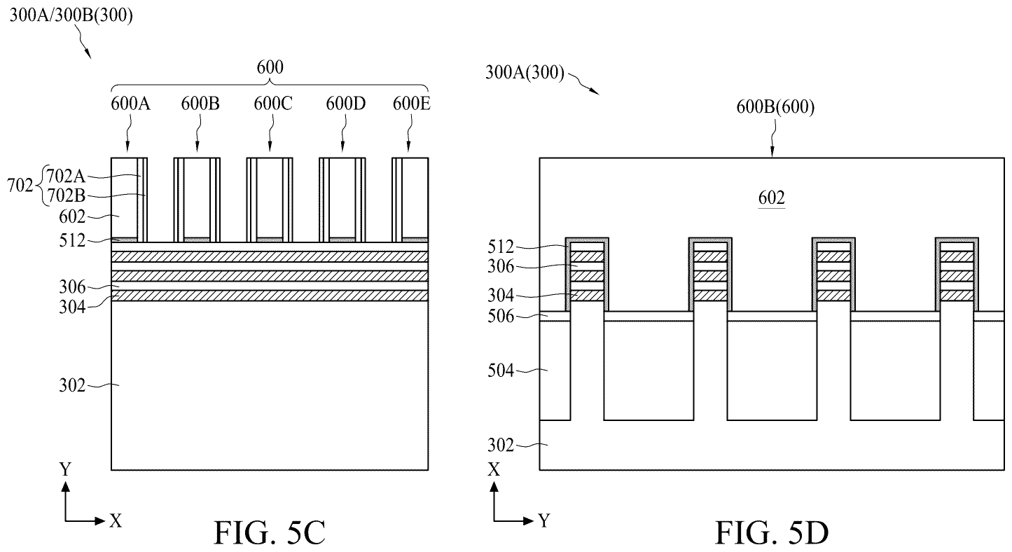

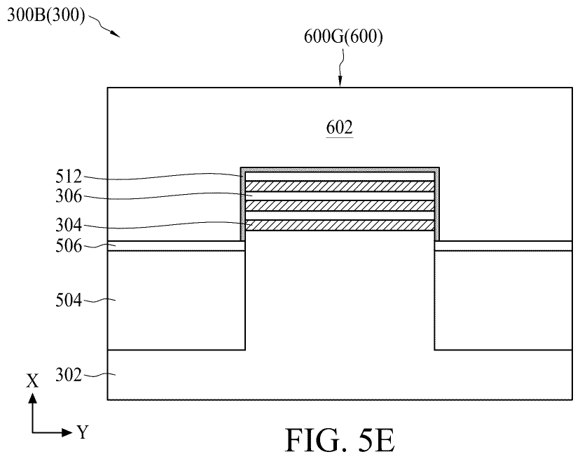

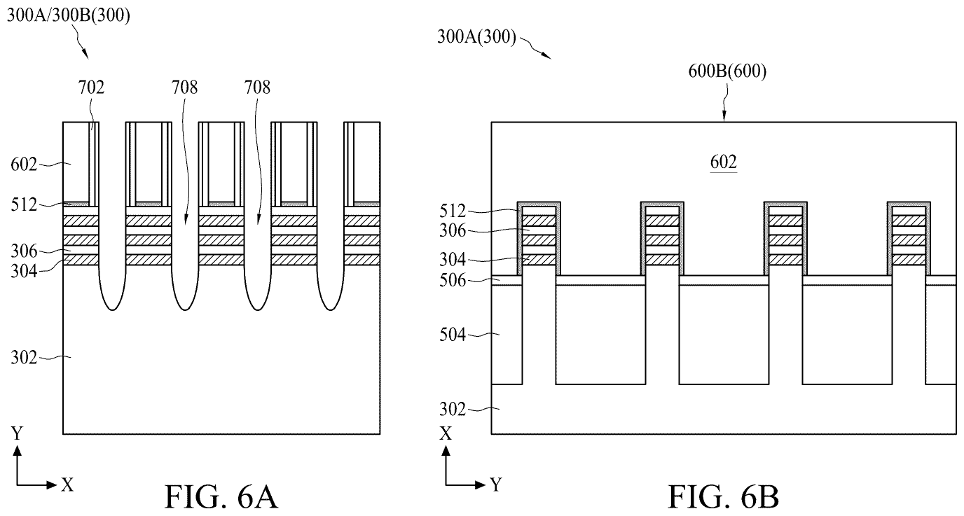

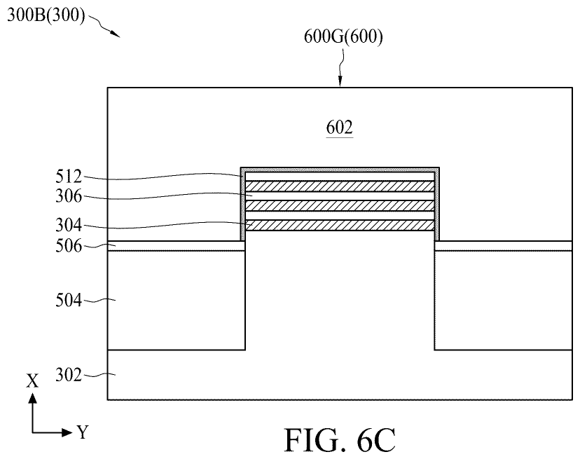

FIGS. 6B, 7B, 8B, 9B, and 10B each illustrate a cross-sectional view of the example semiconductor device taken along line B-B′ of FIG. 5A, in portion or in entirety, during intermediate steps of the method of FIGS. 2A and/or 2B, according to some embodiments of the present disclosure.

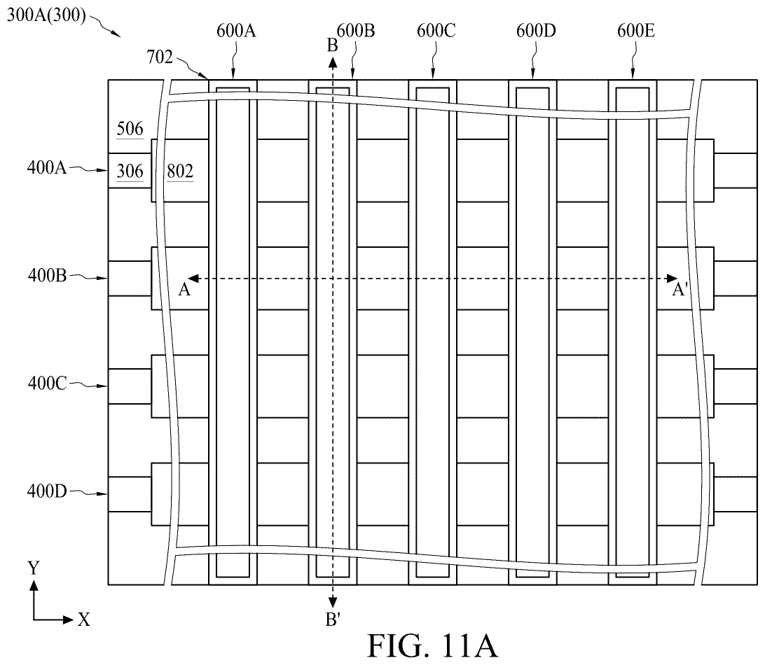

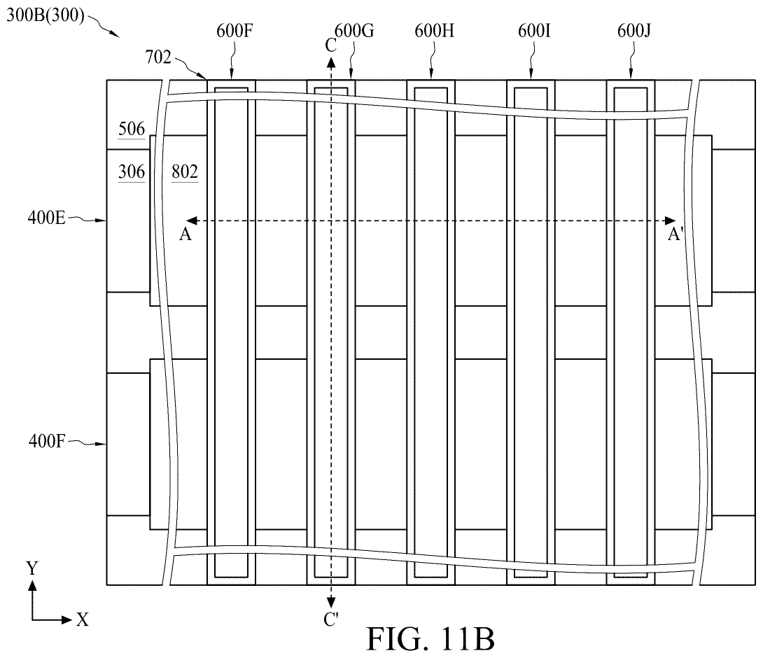

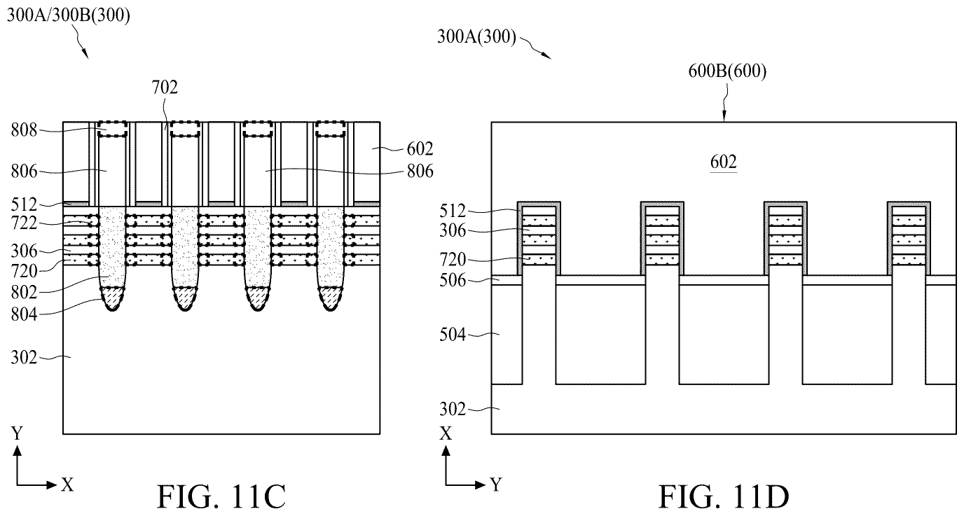

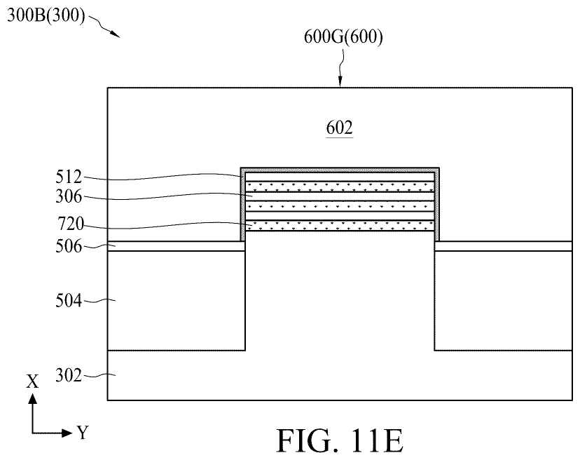

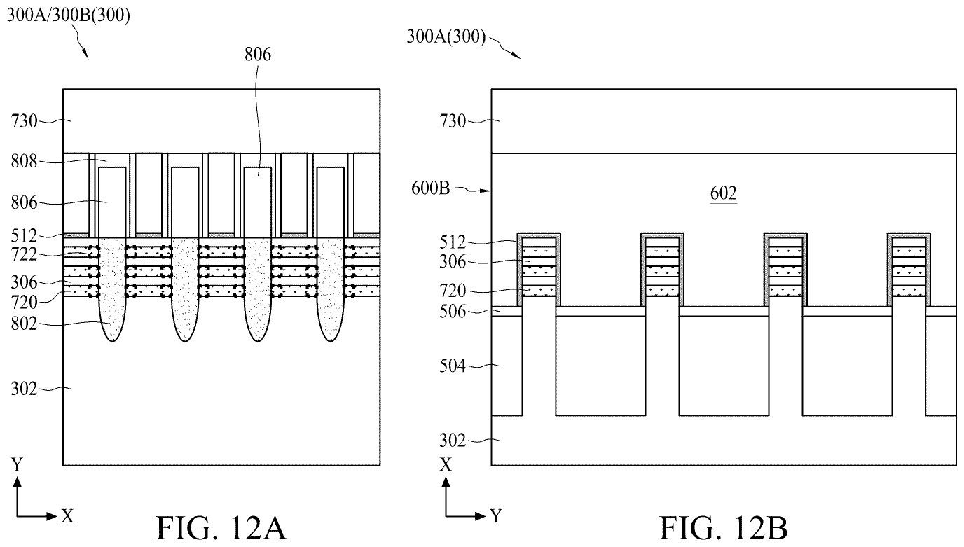

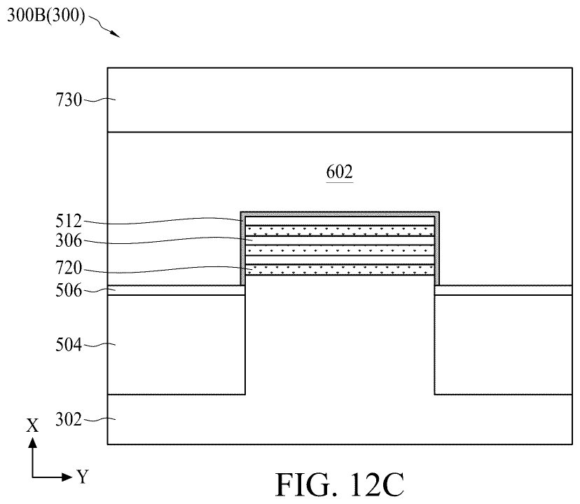

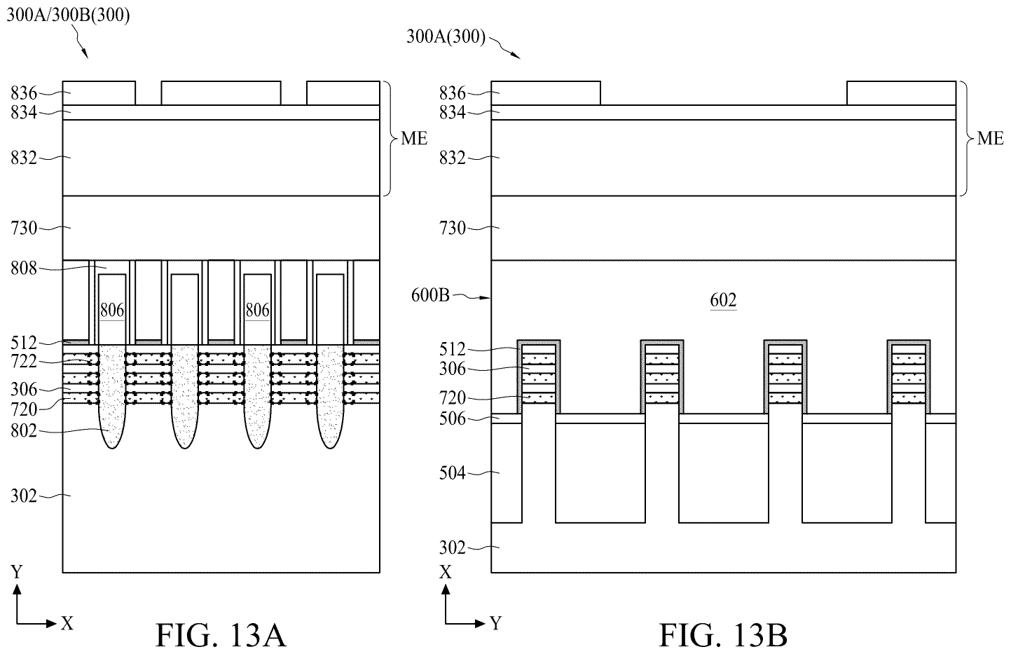

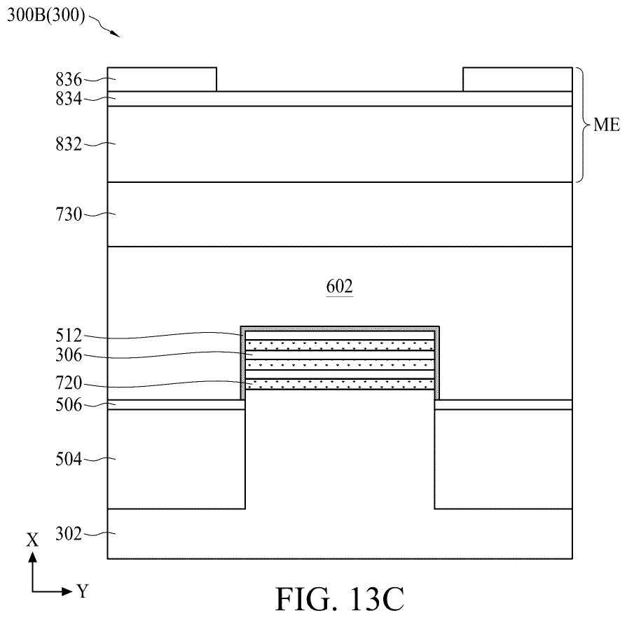

FIGS. 12B and 13B each illustrate a cross-sectional view of the example semiconductor device taken along line B-B′ of FIG. 11A, in portion or in entirety, during intermediate steps of the method of FIGS. 2A and/or 2B, according to some embodiments of the present disclosure.

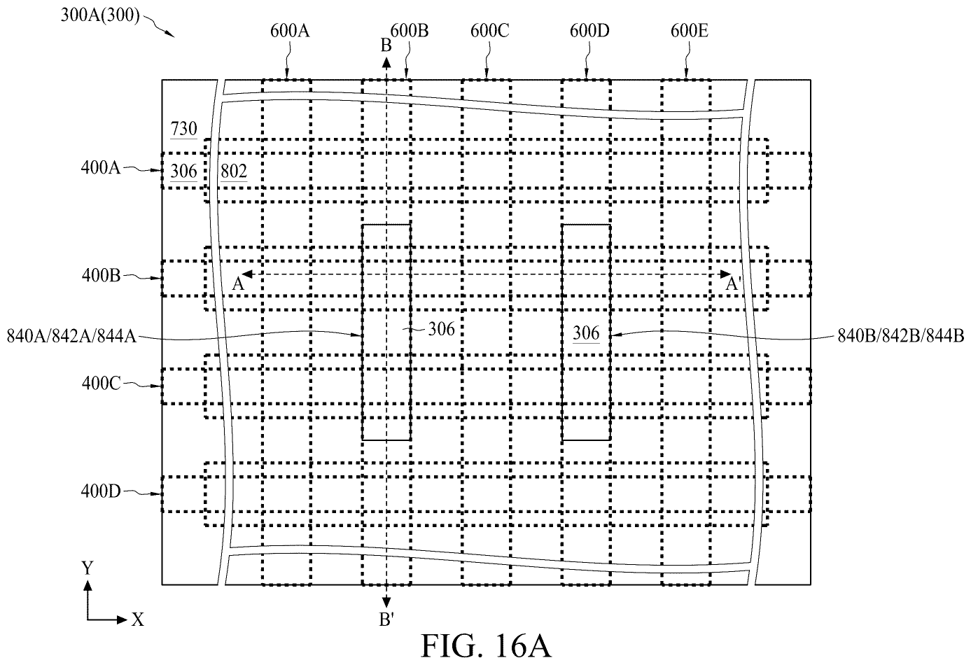

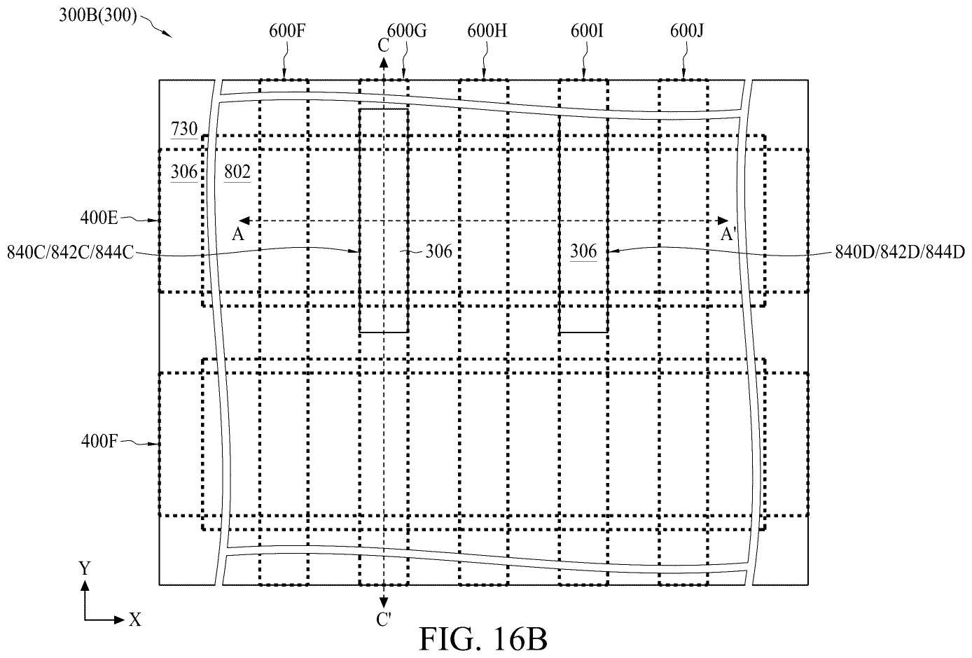

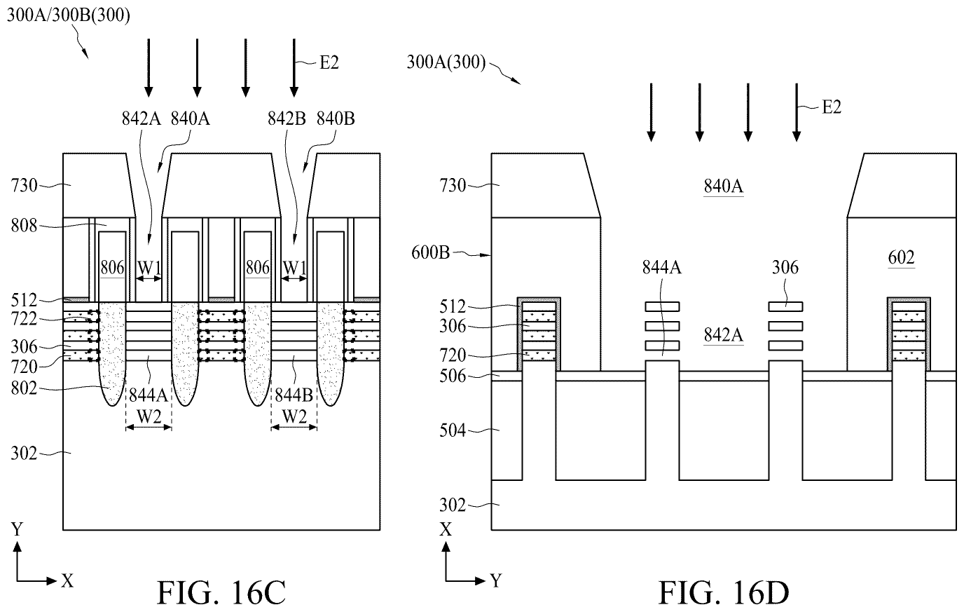

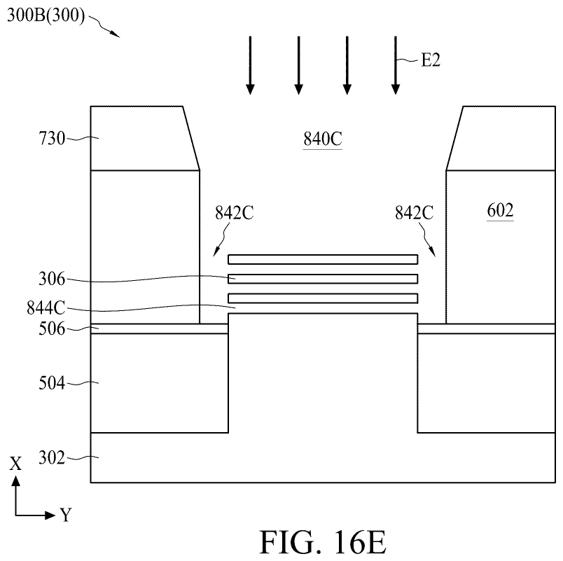

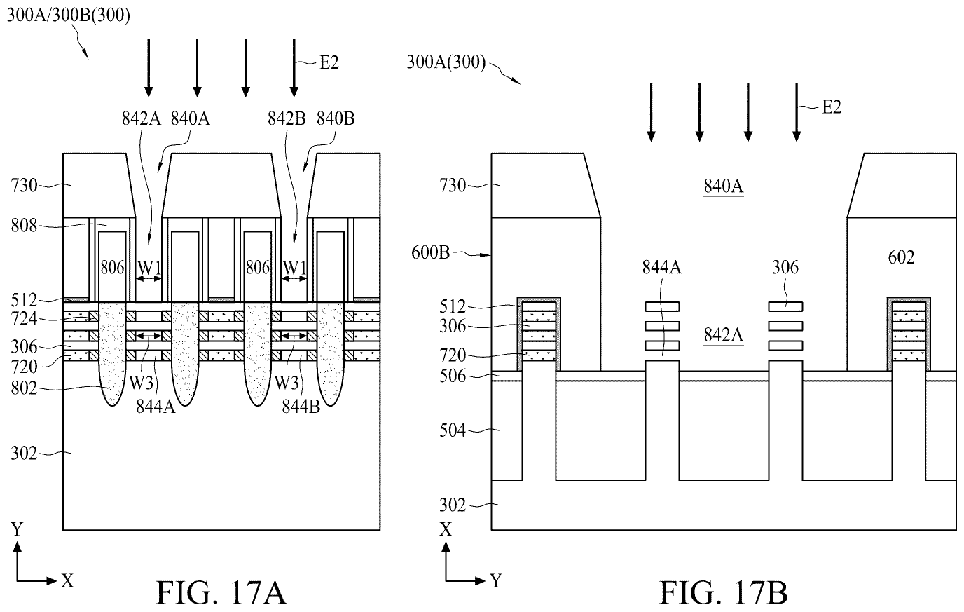

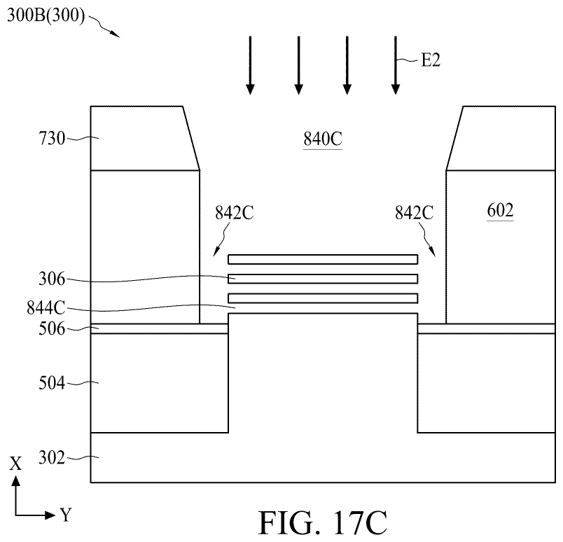

FIG. 17B illustrates a cross-sectional view of the example semiconductor device taken along line B-B′ of FIG. 16A, in portion or in entirety, during intermediate steps of the method of FIGS. 2A and/or 2B, according to some embodiments of the present disclosure.

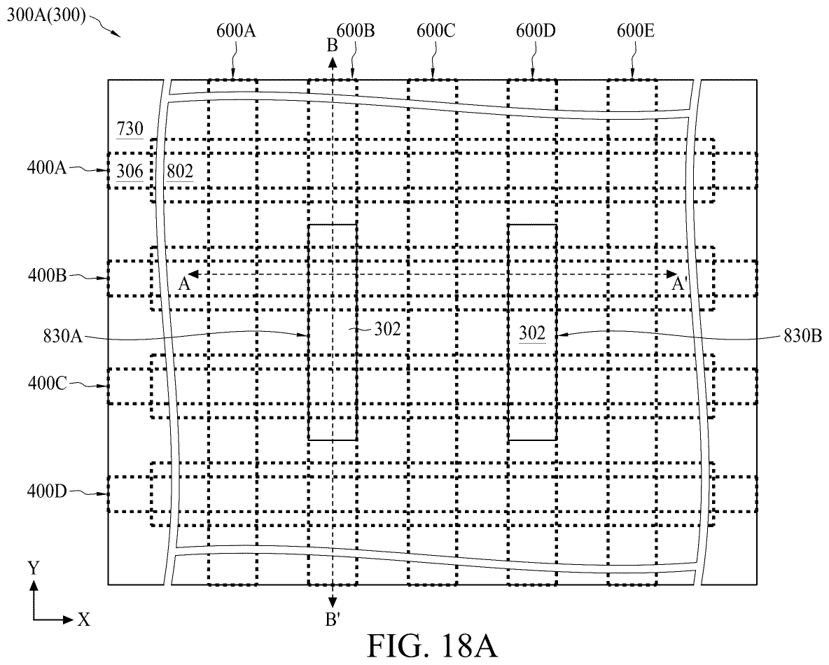

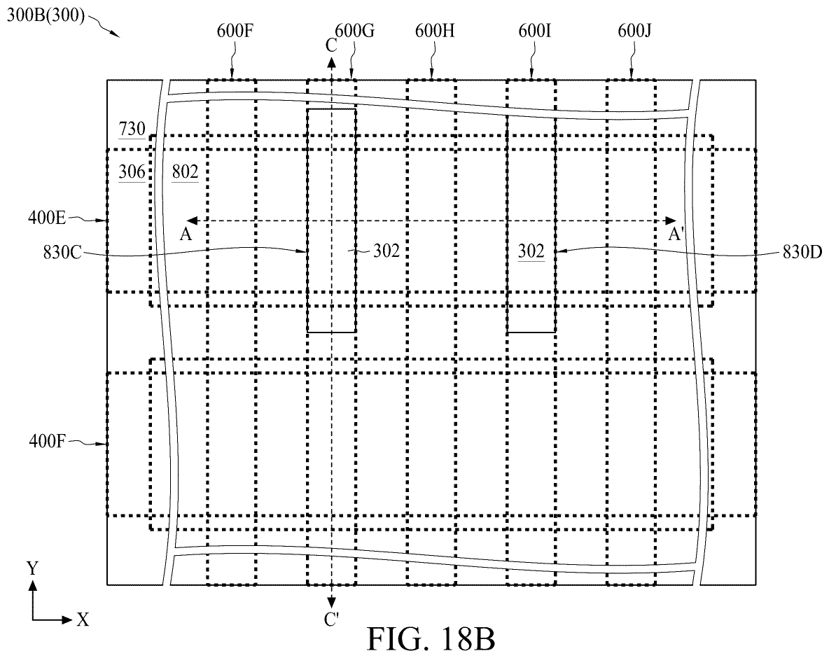

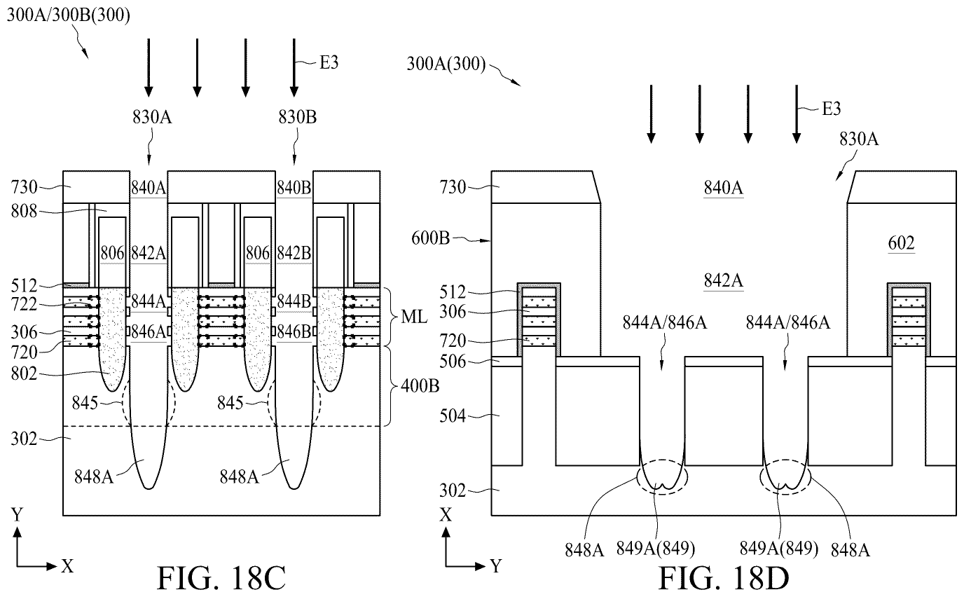

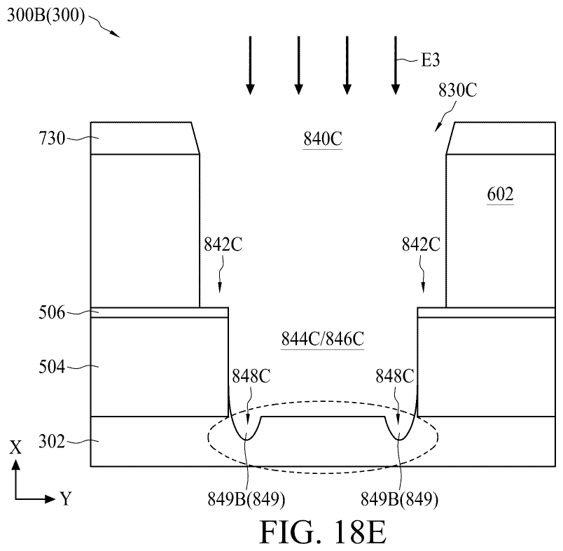

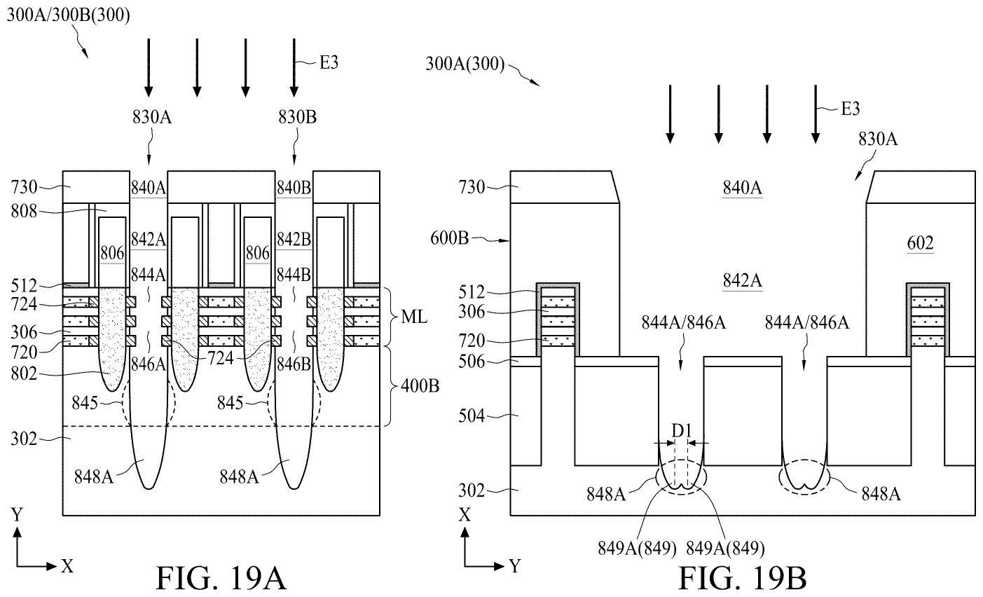

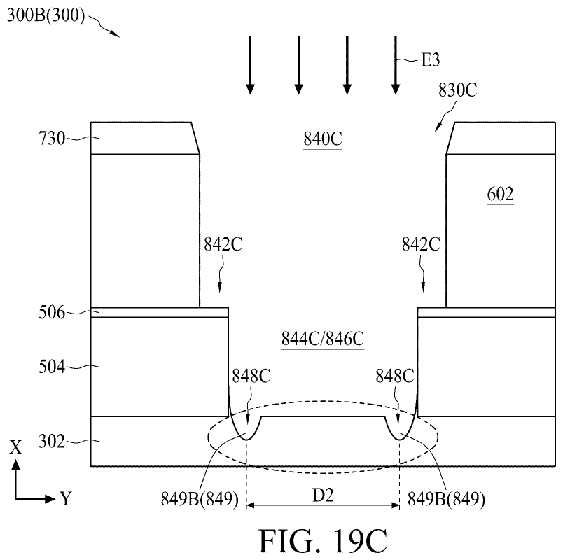

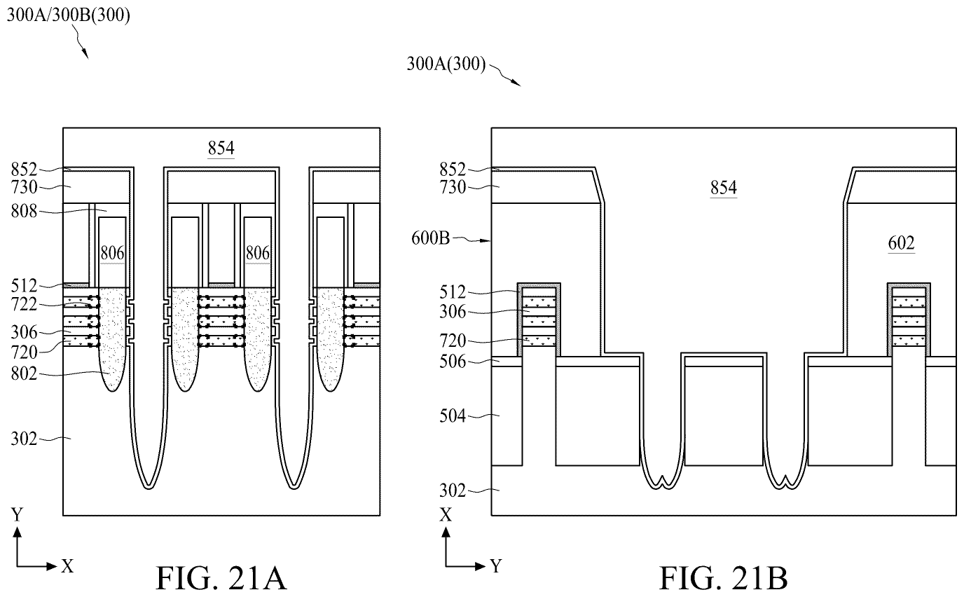

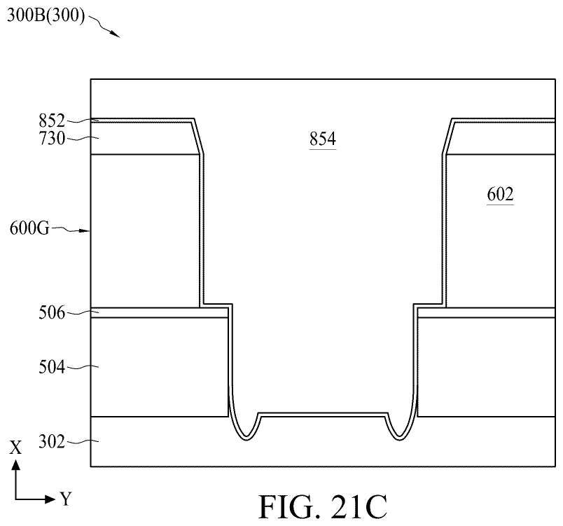

FIGS. 19B and 21B each illustrate a cross-sectional view of the example semiconductor device taken along line B-B′ of FIG. 18A, in portion or in entirety, during intermediate steps of the method of FIGS. 2A and/or 2B, according to some embodiments of the present disclosure.

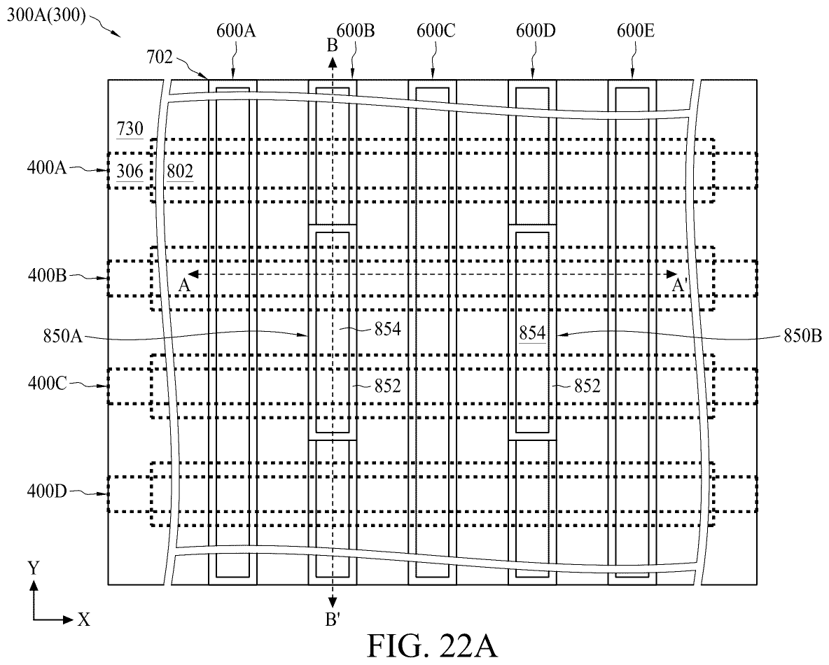

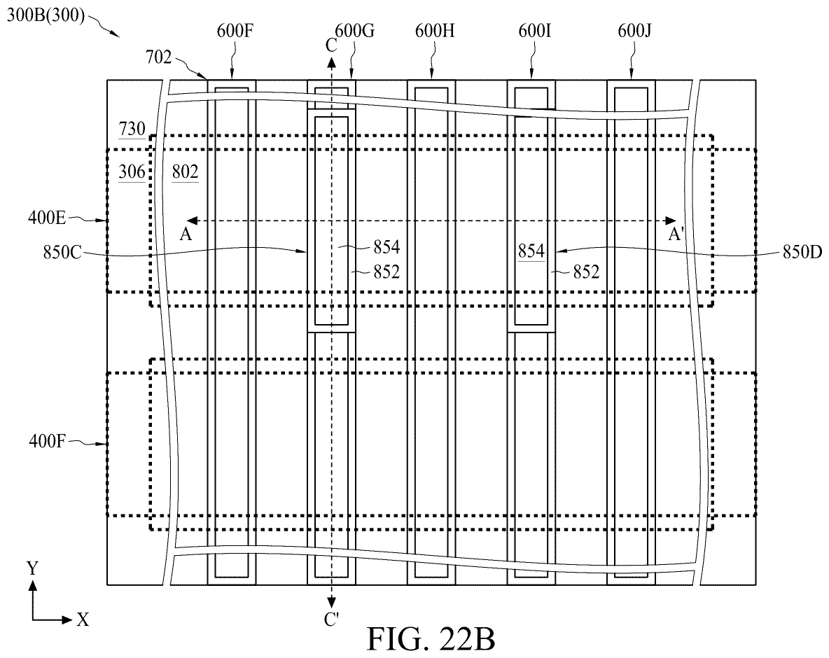

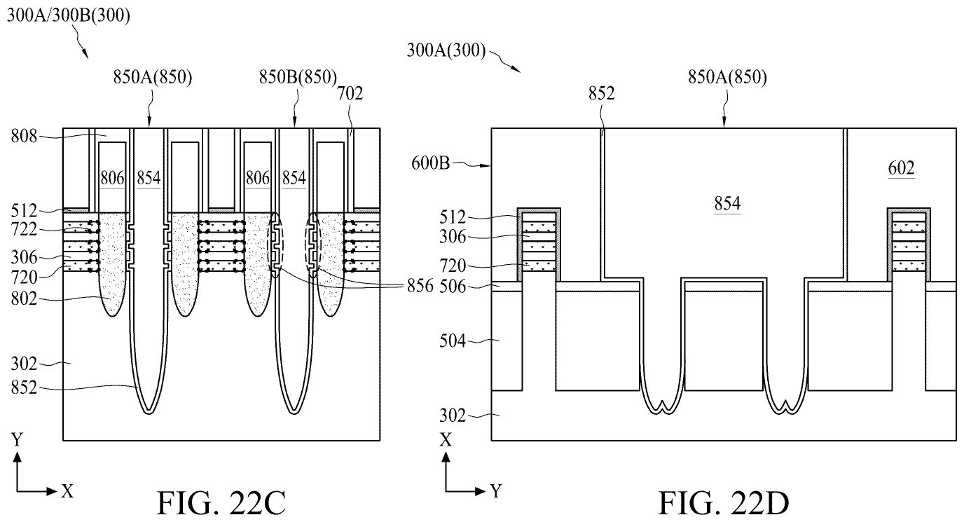

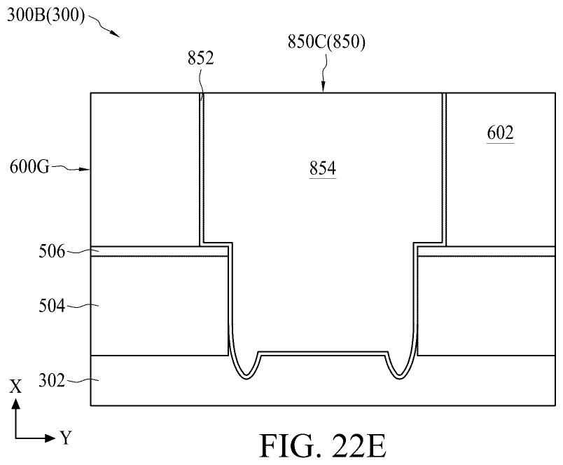

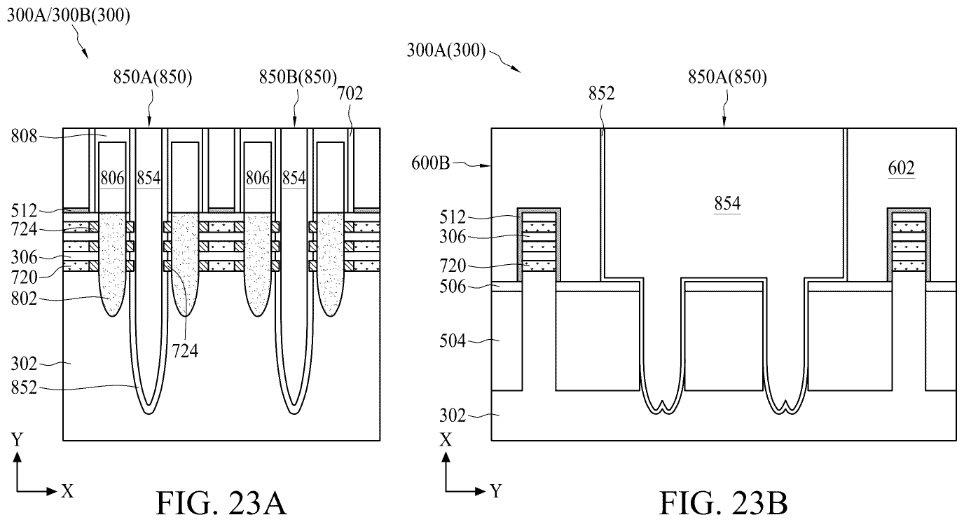

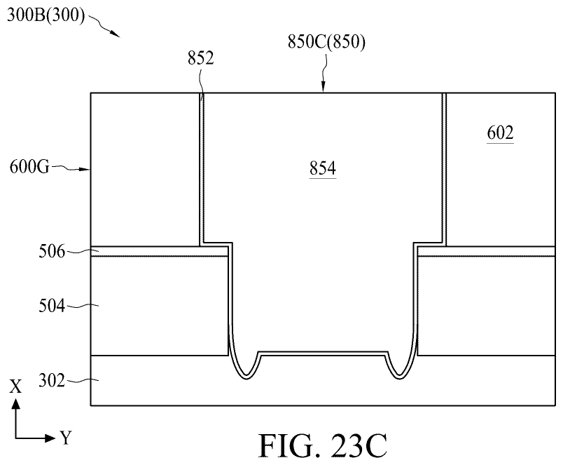

FIGS. 23B, 24B, and 25B each illustrate a cross-sectional view of the example semiconductor device taken along line B-B′ of FIG. 22A, in portion or in entirety, during intermediate steps of the method of FIGS. 2A and/or 2B, according to some embodiments of the present disclosure.

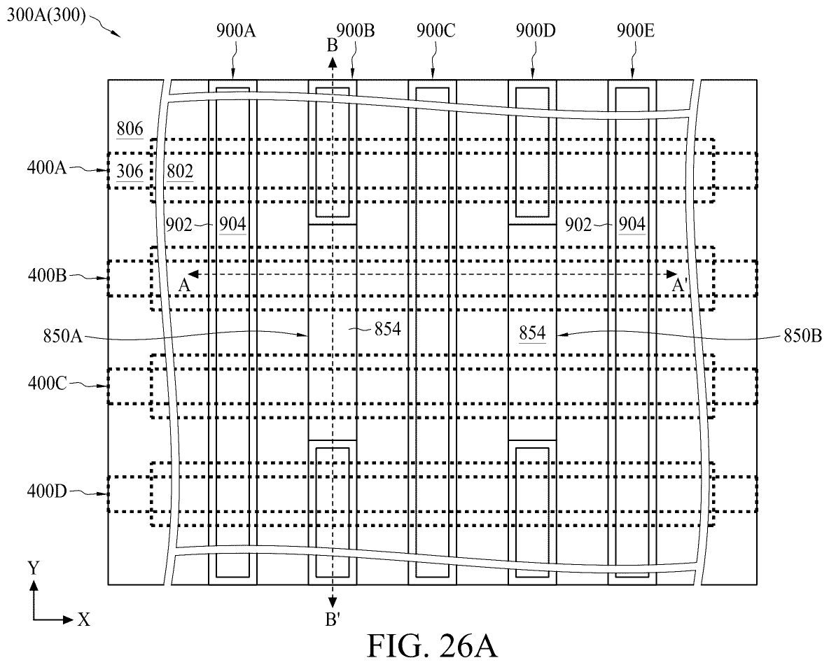

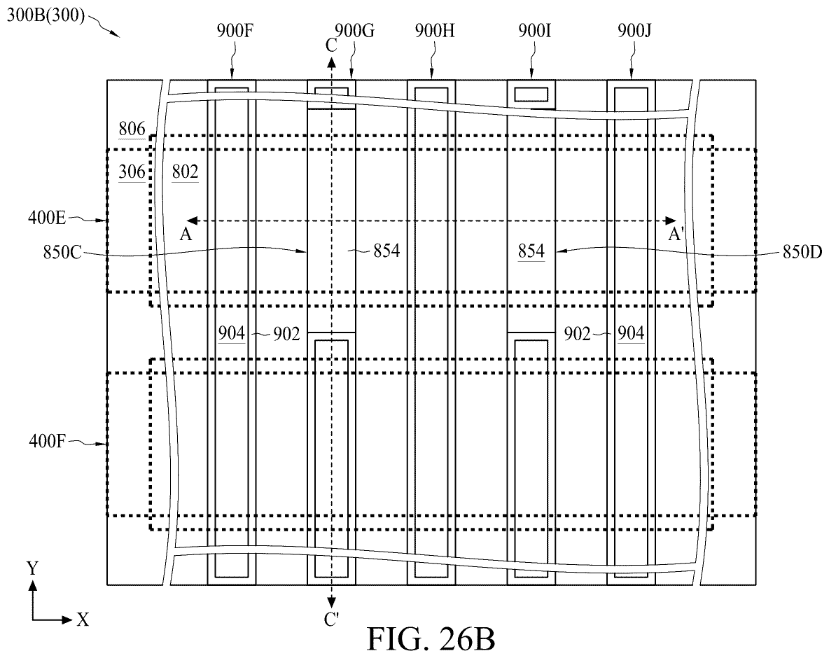

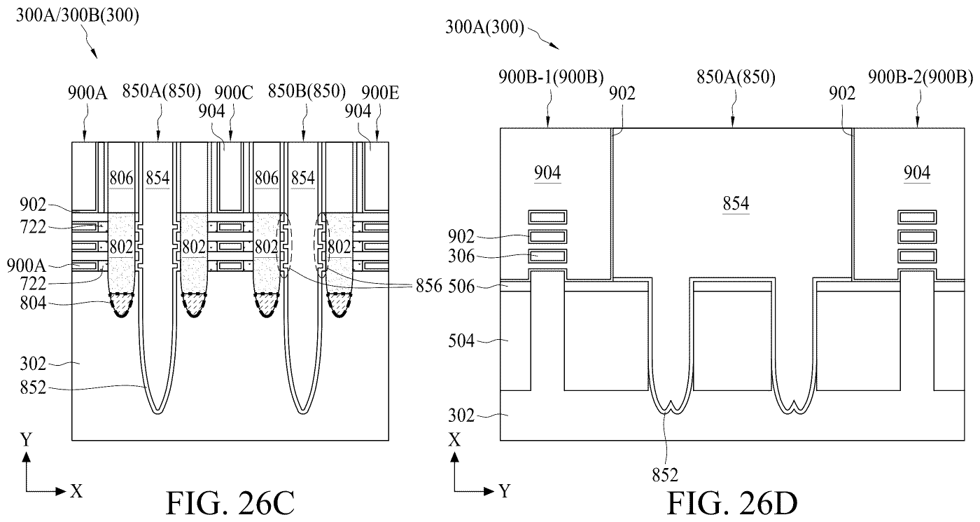

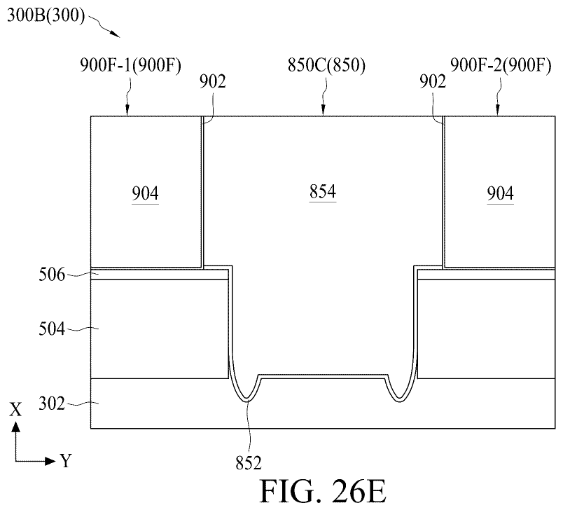

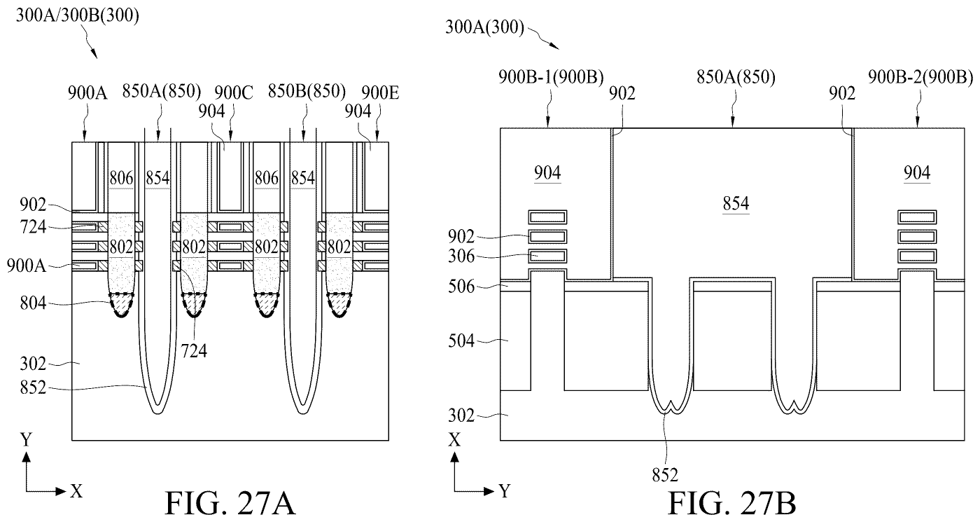

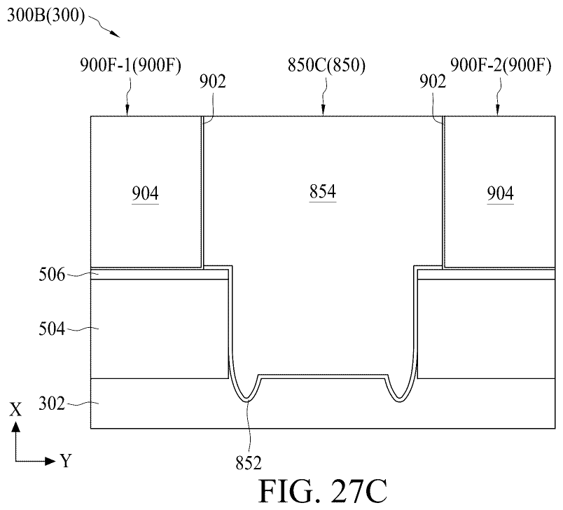

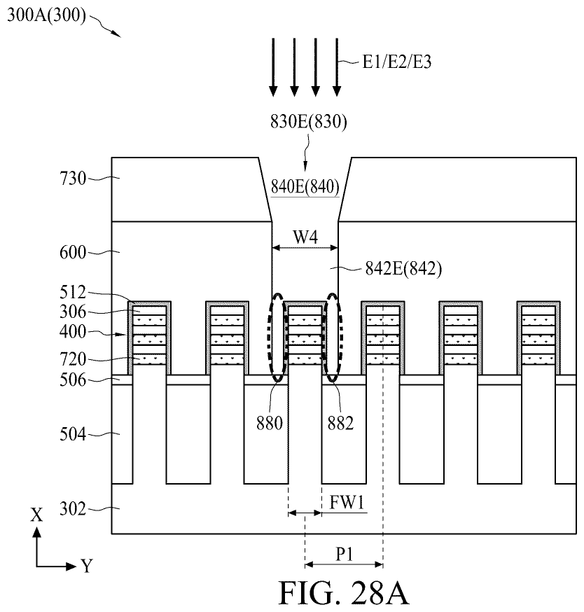

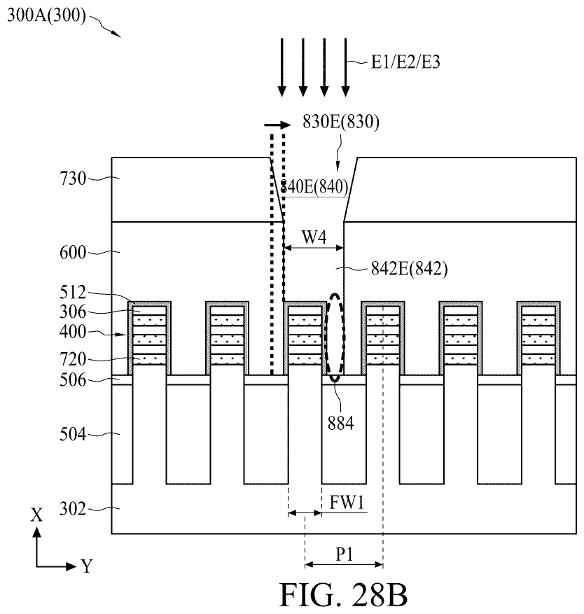

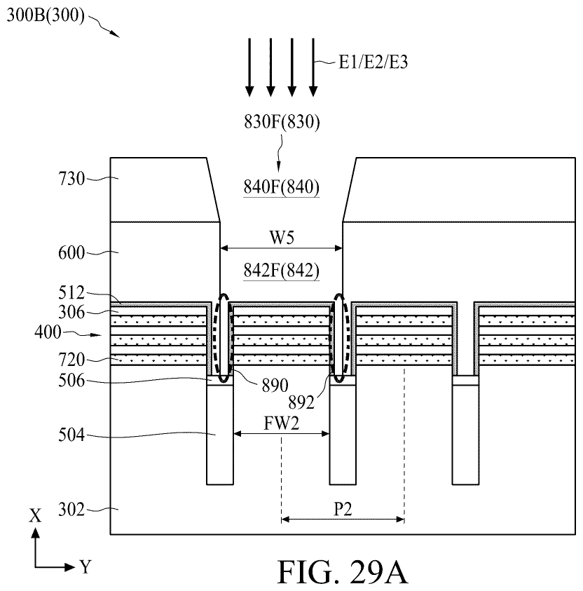

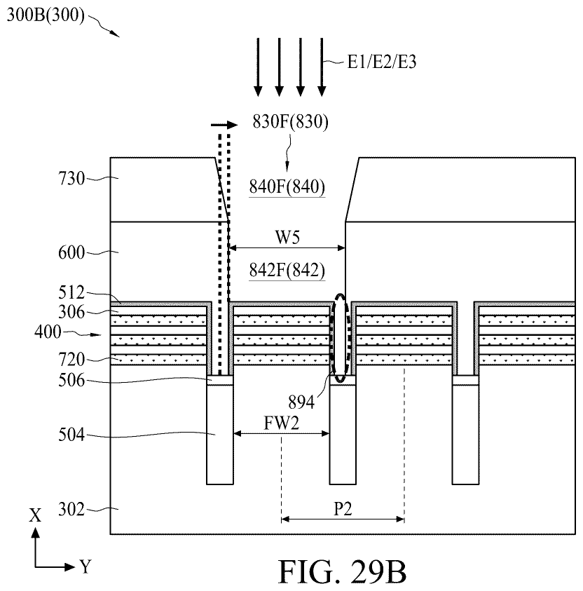

FIG. 27B illustrates a cross-sectional view of the example semiconductor device taken along line B-B′ of FIG. 26A, in portion or in entirety, during intermediate steps of the method of FIGS. 2A and/or 2B, according to some embodiments of the present disclosure.

FIGS. 4E, 5E, 11E, 14E, 15E, 16E, 18E, 22E, and 26E each illustrate a cross-sectional view of the example semiconductor device taken along line C-C′ of FIGS. 4B, 5B, 11B, 14B, 15B, 16B, 18B, 22B, and 26B, respectively, in portion or in entirety, during intermediate steps of the method of FIGS. 2A and/or 2B, according to some embodiments of the present disclosure.

FIGS. 6C, 7C, 8C, 9C, and 10C each illustrate a cross-sectional view of the example semiconductor device taken along line C-C′ of FIG. 5B, in portion or in entirety, during intermediate steps of the method of FIGS. 2A and/or 2B, according to some embodiments of the present disclosure.

FIGS. 12C and 13C each illustrate a cross-sectional view of the example semiconductor device taken along line C-C′ of FIG. 11B, in portion or in entirety, during intermediate steps of the method of FIGS. 2A and/or 2B, according to some embodiments of the present disclosure.

FIG. 17C illustrates a cross-sectional view of the example semiconductor device taken along line C-C′ of FIG. 16B, in portion or in entirety, during intermediate steps of the method of FIGS. 2A and/or 2B, according to some embodiments of the present disclosure.

FIGS. 19C and 21C each illustrate a cross-sectional view of the example semiconductor device taken along line C-C′ of FIG. 18B, in portion or in entirety, during intermediate steps of the method of FIGS. 2A and/or 2B, according to some embodiments of the present disclosure.

FIGS. 23C, 24C, and 25C each illustrate a cross-sectional view of the example semiconductor device taken along line C-C′ of FIG. 22B, in portion or in entirety, during intermediate steps of the method of FIGS. 2A and/or 2B, according to some embodiments of the present disclosure.

FIG. 27C illustrates a cross-sectional view of the example semiconductor device taken along line C-C′ of FIG. 26B, in portion or in entirety, during intermediate steps of the method of FIGS. 2A and/or 2B, according to some embodiments of the present disclosure.

FIGS. 28A, 28B, 29A, and 29B each illustrate a cross-sectional view of an example semiconductor device, in portion or in entirety, according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

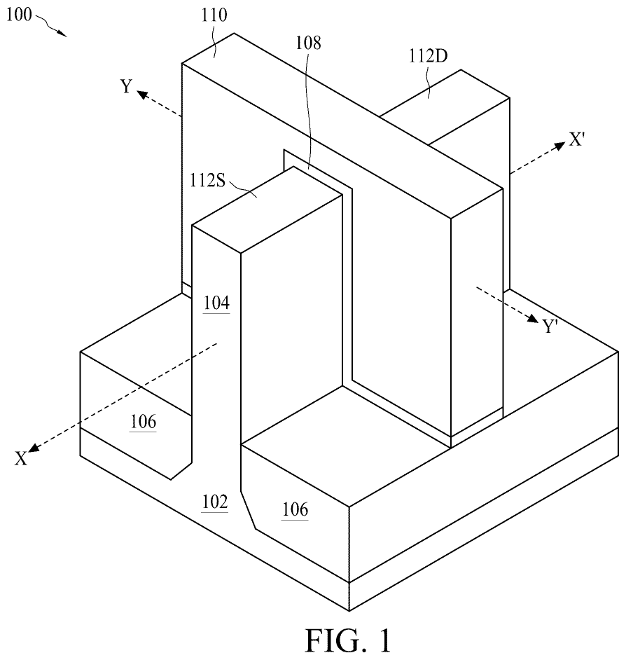

FIG. 1 illustrates a perspective view of an example semiconductor device 100, in accordance with various embodiments. The semiconductor device 100 includes a substrate 102 and a fin 104 protruding from the substrate 102 along a vertical direction (e.g., the Z axis). In some embodiments, the fin 104 includes a single layer of semiconductor material. In some embodiments, the fin 104 includes a plurality of semiconductor layers (e.g., nanosheets, nanorods, etc.) stacked along the vertical direction. Isolation regions 106 are formed on opposing sides of the fin 104, with the fin 104 protruding above the isolation regions 106. A gate dielectric layer 108 is along sidewalls and over a top surface of the fin 104, and a gate electrode layer 110 is over the gate dielectric layer 108, which together form a gate structure. In some embodiments, lower portions of the gate structure are interleaved with (i.e., arranged in an alternate pattern with) the plurality of semiconductor layers along the vertical direction, rendering the semiconductor device 100 a multi-gate device, such as a gate-all-around (GAA) device. Source feature 112S and drain feature 112D (collectively referred to as source/drain features 112S/D) are in (or extended from) the fin 104 and on opposing sides of the gate structure. FIG. 1 is provided as a reference to illustrate a number of cross-sections in subsequent figures. For example, cross-sectional views taken along line Y-Y′ extend along a longitudinal axis of the gate electrode layer 110 of the semiconductor device 100. Cross-sectional views taken along line X-X′ are perpendicular to the cross-section Y-Y′ and along a longitudinal axis of the fin 104 and in a direction of, for example, a current flow between the source/drain features 112S/D. Subsequent figures refer to these reference cross-sections for clarity.

FIG. 2A illustrates a flow chart of an example method 200 for making a semiconductor device 300 (hereafter referred to as “device 300”) in accordance with some embodiments. It should be noted that the method 200 is merely an example and is not intended to limit the present disclosure. Accordingly, it is understood that additional steps/operations may be provided before, during, and after the method 200 of FIG. 2A, and that some other operations may only be briefly described herein. In some embodiments, certain operations of the method 200 are described in detail in a flow chart illustrated in FIG. 2B.

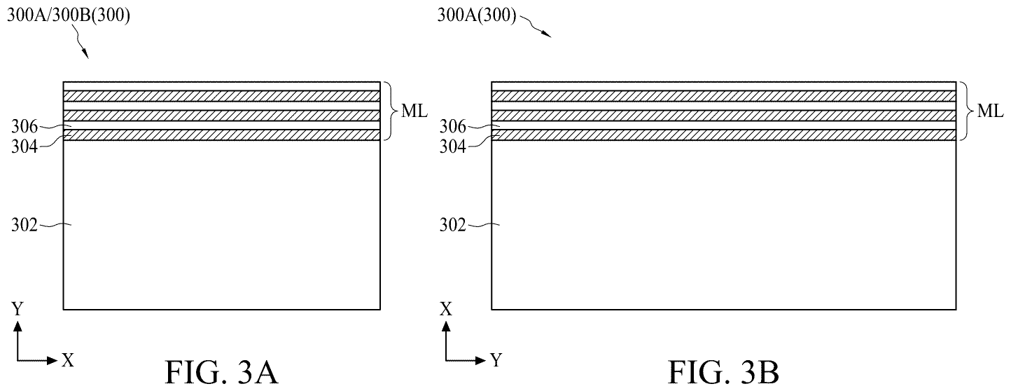

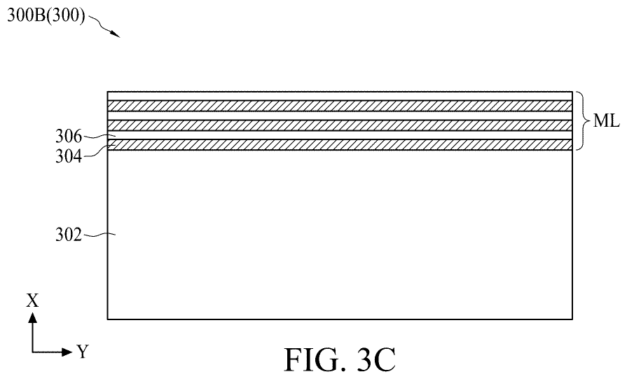

Operations of the method 200 may be associated with top views and cross-sectional views of the device 300 at various fabrication stages as shown in FIGS. 3A-27C, which will be described in further detail below. For example, FIGS. 4A, 5A, 11A, 14A, 15A, 16A, 18A, 22A, and 26A each illustrate a top view of an example device 300A, which is an embodiment of the device 300; FIGS. 4B, 5B, 11B, 14B, 15B, 16B, 18B, 22B, and 26B each illustrate a top view of an example device 300B, which is an embodiment of the device 300; FIGS. 4C, 5C, 6A, 7A, 8A, 9A, 10A, 11C, 12A, 13A, 14C, 15C, 16C, 17A, 18C, 19A, 20, 21A, 22C, 23A, 24A, 25A, 26C, and 27A illustrate cross-sectional views of the device 300A or 300B taken along line A-A′ (e.g., the line X-X′) of one or more of the corresponding FIGS. 4A, 4B, 5A, 5B, 11A, 11B, 14A, 14B, 15A, 15B, 16A, 16B, 18A, 18B, 22A, 21B, 26A, and 26B; FIGS. 4D, 5D, 6B, 7B, 8B, 9B, 10B, 11D, 12B, 13B, 14D, 15D, 16D, 17B, 18D, 19B, 21B, 22D, 23B, 24B, 25B, 26D, and 27B illustrate cross-sectional views of the device 300A taken along line B-B′ (e.g., the line Y-Y′) of one or more of the corresponding FIGS. 4A, 5A, 11A, 14A, 15A, 16A, 18A, 22A, and 26A; and FIGS. 4E 5E, 6C, 7C, 8C, 9C, 10C, 11E, 12C, 13C, 14E, 15E, 16E, 17C, 18E, 19C, 21C, 22E, 23C, 24C, 25C, 26E, and 27C illustrate cross-sectional views of the device 300B taken along line C-C′ (e.g., the line Y-Y′) of one or more of the corresponding FIGS. 4B, 5B, 11B, 14B, 15B, 16B, 18B, 22B, and 26B.

In some embodiments, the device 300A and the device 300B may be provided on a common substrate and may thus represent different device regions on the common substrate. It is understood that features common to the device 300A and 300B are described using the same numerals for purposes of brevity. Furthermore, wherever appropriate, the device 300A and the device 300B may be collectively referred to as the device 300.

In brief overview, referring to FIG. 2A, the device 300 may be formed by implementing operations 202 to 226, according to some embodiments. For example, the method 200 begins with operation 202 of providing a substrate overlaid by a multilayer stack of first semiconductor layers interleaved with second semiconductor layers. The method 200 proceeds to operation 204 of forming fin structures in the multilayer stack protruding from the substrate. The method 200 proceeds to operation 206 of forming isolation structures over the substrate and adjacent to the fin structures. The method 200 proceeds to operation 208 of forming dummy gate structures over the fin structures. Next, the method 200 proceeds to operation 210 of forming source/drain recesses adjacent to each dummy gate structure. The method 200 proceeds to operation 212 of replacing the first semiconductor layers with sacrificial layers. The method 200 proceeds to operation 214 of forming inner spacers at an end portion of each sacrificial layer. The method 200 proceeds to operation 216 of forming source/drain features to fill the source/drain recesses. The method 200 proceeds to operation 218 of forming fin isolation structures. The method 200 proceeds to operation 220 of removing the dummy gate structures. Next, the method 200 proceeds to operation 222 of removing the remaining sacrificial layers. The method 200 proceeds to operation 224 of forming active gate structures in place of the dummy gate structures and the sacrificial layers. The method 200 thereafter proceeds to operation 226 of performing any additional operations to complete fabrication of the device 300.

Referring to FIGS. 2A and 3A-3C, a substrate 302 is provided in the device 300 at the operation 202. The substrate 302 is overlaid with a multilayer structure (ML) of a number of first semiconductor layers 304 interleaved with a number of second semiconductor layers 306 (alternatively referred to as semiconductor sacrificial layers 306). In other words, the first semiconductor layers 304 and the second semiconductor layers 306 are alternatingly stacked as the ML on a top surface of the substrate 302. It should be understood that the device 300 can include any number of first semiconductor layers 304 and any number of second semiconductor layers 306 (which serve as channel layers), with either one of them being the topmost layer, while remaining within the scope of the present disclosure.

In some embodiments, the substrate 302 includes a semiconductor material such as silicon (Si), silicon germanium (SiGe), a compound semiconductor such as silicon carbide, gallium arsenide, gallium phosphide, indium phosphide, indium arsenide, and/or indium antimonide, an alloy semiconductor such as GaAsP, AlInAs, AlGaAs, InGaAs, GaInP, and/or GaInAsP, any other suitable materials, or combinations thereof. In some embodiments, the substrate 302 includes an epitaxial layer. For example, the substrate 302 may include an epitaxial layer overlying a bulk semiconductor. Furthermore, the substrate 302 may include a semiconductor-on-insulator (SOI) structure. For example, the substrate 302 may include a buried oxide (BOX) layer formed by a process such as separation by implanted oxygen (SIMOX) or other suitable technique, such as wafer bonding and grinding.

The semiconductor layers 304 and 306 have different compositions. In various embodiments, the semiconductor layers 304 and 306 have compositions that provide for different oxidation rates and/or different etch selectivity between the layers. In the present embodiments, the first semiconductor layers 304 include silicon germanium (Si₁₋ₓGeₓ), and the second semiconductor layers 306 include silicon (Si). Either of the semiconductor layers 304 and 306 may include other materials, for example, a compound semiconductor such as silicon carbide, gallium arsenide, gallium phosphide, indium phosphide, indium arsenide, and/or indium antimonide, an alloy semiconductor such as GaAsP, AlInAs, AlGaAs, InGaAs, GaInP, and/or GaInAsP, any other suitable material, or combinations thereof. The materials of the semiconductor layers 304 and 306 may be chosen to provide different oxidation rates and/or etch selectivity.

The semiconductor layers 304 and 306 may have different thicknesses. The first semiconductor layers 304 may have different thicknesses from one layer to another layer. The second semiconductor layers 306 may have different thicknesses from one layer to another layer. The first layer of the ML may be thicker than other semiconductor layers 304 and 306. Either the first semiconductor layer 304 or the second semiconductor layer 306 may be the topmost layer (or the layer farthest from the substrate 302). In an embodiment, the first semiconductor layer 304 may be the bottommost layer (or the layer most proximate to the substrate 302) of the ML.

The semiconductor layers 304 and 306 can be grown from the substrate 302. For example, each of the semiconductor layers 304 and 306 may be grown by a molecular beam epitaxy (MBE) process, a chemical vapor deposition (CVD) process such as a metal organic CVD (MOCVD) process, and/or other suitable growth processes. During the epitaxial growth, the crystal structure of the substrate 302 extends upwardly, resulting in the semiconductor layers 304 and 306 having the same crystal orientation with the substrate 302.

Referring to FIGS. 2A and 4A-4E, fin structures 400A, 400B, 400C, 400D, 400E, and 400F (collectively referred to as fin structures 400) are formed in the ML at the operation 204. Specifically, the fin structures 400A-400D are formed in the device 300A and the fin structures 400E and 400F are formed in the device 300B. The fin structures 400 each extend along a first lateral direction (e.g., the X axis) and spaced from one another along a second lateral direction (e.g., the Y axis) perpendicular to the first lateral direction. It is appreciated that the device 300 may include any suitable number of fin structures 400 while remaining within the scope of the present disclosure.

The fin structures 400 are formed by patterning the ML of semiconductor layers 304 and 306 and a top portion of the substrate 302 using, for example, photolithography and etching techniques. For example, a mask layer (which can include multiple layers such as, for example, a pad oxide layer and an overlying pad nitride layer; not depicted) is formed over a top surface of the ML. The pad oxide layer and the pad nitride layer may be formed using thermal oxidation, CVD, low-pressure chemical vapor deposition (LPCVD), or plasma enhanced chemical vapor deposition (PECVD), for example.

The mask layer may then be patterned using photolithography techniques. Generally, photolithography techniques utilize a photoresist material (not shown) that is deposited, irradiated (exposed) through a photolithography mask, and developed to remove a portion of the photoresist material. The remaining photoresist material protects the underlying material, such as the mask layer in this example, from subsequent processing steps, such as etching. For example, the photoresist material is used to pattern the pad oxide layer and pad nitride layer to form a patterned mask. The photoresist material may be removed by a suitable method, such as plasma ashing or resist stripping, after patterning the mask layer.

The patterned mask is subsequently used to pattern exposed portions of the semiconductor layers 304 and 306 and the substrate 302 to form trenches (or openings) 410, thereby defining the fin structures 400 between adjacent trenches 410, as illustrated in FIGS. 4B and 4C. The trenches 410 continuously extend along the first lateral direction. When multiple fin structures 400 are formed, such a trench 410 may be disposed between any adjacent ones of the fin structures. In some embodiments, the fin structures 400 are formed by etching trenches 410 in the semiconductor layers 304 and 306 and the substrate 302 using, for example, a dry etching process, e.g., a reactive ion etching (RIE) process, a neutral beam etching (NBE) process, other suitable process, or combinations thereof. The etching process may be anisotropic. In some embodiments, the patterned mask remains over the is removed at a later operation, such as during a chemical mechanical polish (CMP) process, for example.

In the present embodiments, the fin structures 400A-400D are each formed to have a fin width FW1 (alternatively referred to as sheet width), and the fin structures 400E and 400F are each formed to a fin width FW2 that is greater than the fin width FW1. For purposes of illustration, the fin width FW1 may be less than or equal to about 60 nm and the fin width FW2 may be about at least 60 nm.

Referring to FIGS. 2A and 5A-5E, isolation structures 504 (alternatively referred to as isolation regions) are formed at the operation 206. As shown in FIGS. 5D and 5E, the isolation structures 504 can be formed between adjacent ones of the fin structures 400, and partially embed or surround lower portions of the adjacent fin structures 400.

In some embodiments, the isolation structures 504 are configured to electrically isolate neighboring active structures (e.g., adjacent fin structures or adjacent stacks of nanostructure channel layers) from one another. The isolation structures 504 may include an oxide, such as silicon oxide, a nitride, a low-k dielectric material (e.g., a dielectric material having a dielectric constant less than that of silicon oxide, which is about 3.9), such as phosphosilicate glass (PSG), borosilicate glass (BSG), boron-doped phosphosilicate glass (BPSG), undoped silicate glass (USG), other suitable materials, or combinations thereof.

The isolation structures 504 may be formed by first depositing an insulation material by any suitable process, such as high-density plasma chemical vapor deposition (HDP-CVD), flowable CVD (FCVD) (e.g., a CVD-based material deposition process in a remote plasma system and post curing to make it convert to another material, such as an oxide), other suitable processes, or combinations thereof. An anneal process may be performed once the insulation material is formed. A planarization process, such as a CMP process or any other suitable process, may be performed remove any excess insulation material to expos a top surface of the fin structures 400 or the patterned mask, if present. The patterned mask may be removed by the planarization process, in some other embodiments. Subsequently, the insulation material is recessed to form the isolation structures 504, which are sometimes referred to as shallow trench isolations (STIs). The isolation structures 504 are recessed such that the fin structures 400 protrude from between neighboring isolation structures 504. The isolation structures 504 may be recessed to where a top surface of the isolation structures 504 is below the substrate 302. The isolation structures 504 may be recessed using a suitable etching process, such as one that is selective to the material of the isolation structures 504. For example, a dry etching process or a wet etching process using dilute hydrofluoric (dHF) acid may be performed to recess the isolation structures 504.

In the present embodiments, an oxide layer 512 is formed over surfaces, including top and sidewall surfaces, of each of the fin structures 400 and top surfaces of the isolation structures 504. In various embodiments, the oxide layer 512 includes silicon oxide. The oxide layer 512 may be formed by conformally depositing an oxide layer using a process such as CVD or atomic layer deposition (ALD), over the fin structure 400 and the isolation structures 504. In some embodiments, the oxide layer 512 is formed as a part of an I/O device that is also fabricated on the substrate 302.

Subsequently, a hard mask 506 (alternatively referred to as a dielectric protective layer 506) is formed over the oxide layer 512. As will be described in detail below, the hard mask 506 is configured to resist, or substantially resist, etching of or other inadvertent damage to the underlying isolation structures 504 during subsequent operations. The hard mask 506 includes a dielectric material different from that of the isolation structures 504 in composition such that etching selectivity may be achieved or improved between these two layers. In some embodiments, the isolation structures 504 include an oxide (e.g., silicon oxide) and the hard mask 506 includes a nitride (e.g., silicon nitride). In some embodiments, the isolation structures 504 includes an oxide at a first amount and a nitride at a second amount that is less than the first amount, and the hard mask 506 includes an oxide at a first amount and a nitride at a second amount that is greater than the first amount. The hard mask 506 may be formed by depositing a dielectric layer, using a suitable process such as CVD or ALD, over the device 300, and removing (or etching back) portions of the dielectric layer formed over the top and sidewall surfaces of the fin structures 400, leaving behind the hard mask 506 overlaying the top surfaces of the isolation structures 504.

Referring to FIGS. 2A and 5A-5E, dummy gates structures 600A, 600B, 600C, 600D, 600E, 600F, 600G, 600H, 600I, and 600J (collectively referred to as dummy gate structures 600) are formed over the fin structures 400 at the operation 208. Specifically, the dummy gate structures 600A-600E are formed in the device 300A and the dummy gate structures 600F-600J are formed in the device 300B. The dummy gate structures 600 each extend along the second lateral direction and spaced apart along the first lateral direction. In this regard, the dummy gate structure 600 are generally disposed perpendicular to the fin structures 400. In the present embodiments, the dummy gate structures 600 are placed where an active (e.g., metal) gate structure may later be formed. It is appreciated that the device 300 may include any suitable number of dummy gate structures 600 while remaining within the scope of the present disclosure.

In some embodiments, forming the dummy gate structures 600 includes depositing an etch-stop layer (not depicted) over a top surface of the fin structures 400, where the etch-stop layer is configured to protect the underlying fin structures 400 and may include silicon oxide or any other suitable material. Then, a dummy gate electrode layer 602 including polysilicon, for example, is deposited over the etch-stop layer as a blanket layer. In some embodiments, a hard mask (not depicted) is deposited over the dummy gate electrode layer 602 and subsequently patterned using a photolithography process described herein to form a patterned hard mask. The patterned hard mask may include a nitride (e.g., silicon nitride) layer over the dummy gate electrode layer 602 and an oxide (e.g., silicon oxide) layer deposited over the nitride layer. The patterned hard mask may substantially remain over the dummy gate structures 600 and be removed at a later operation, such as during a CMP process performed after forming source/drain features 802, for example. The dummy gate electrode layer 602 is then patterned using the patterned hard mask as an etch mask, resulting in the dummy gate structures 600.

In some embodiments, though not depicted, the dummy gate structures 600 each further include a dummy gate dielectric layer (not shown) disposed between the etch-stop layer and the dummy gate electrode layer. The dummy gate dielectric layer may include, for example, silicon oxide, silicon nitride, silicon oxynitride, multilayers thereof, other suitable dielectric materials, or combinations thereof, and may be formed by thermal oxidation, chemical oxidation, CVD, ALD, other suitable methods, or combinations thereof.

Still referring to FIGS. 5A-5E, gate spacers 702 are formed on opposing sidewalls of each dummy gate structure 600. The gate spacers 702, which are alternatively referred to as top gate spacers 702, may include any suitable dielectric materials having various amounts of silicon, oxygen, carbon, and nitrogen. For example, the gate spacers 702 may include silicon oxide, silicon nitride, silicon oxynitride, silicon carbonitride, silicon oxycarbonitride, silicon oxycarbide, other suitable materials, combinations thereof. In the depicted embodiments, the gate spacers 702 include multiple spacer layers, such as a first (or inner) spacer layer 702A directly contacting the dummy gate structures 600 and a second (or outer) spacer layer 702B over the first spacer layer 702A, where the multiple spacer layers include different dielectric materials. In some embodiments, the first spacer layer 702A includes a higher amount of an oxide (e.g., silicon oxide) than a nitride (e.g., silicon nitride), and the second spacer layer 702B includes a higher amount of a nitride (e.g., silicon nitride) than an oxide (e.g., silicon oxide). The gate spacers 702 may include any suitable number of additional spacer layers.

The gate spacers 702 (or each spacer layer thereof) may be formed by first conformally depositing one or more dielectric materials over the dummy gate structures 600. Any suitable deposition method, such as thermal oxidation, chemical oxidation, CVD, ALD, other suitable methods, or combinations thereof, may be used to deposit the dielectric materials. Then, the dielectric material(s) may be etched using a suitable etching process, such as an anisotropic dry etching process, to form the gate spacers 702 along the opposing sidewalls of the dummy gate structures 600.

Referring to FIGS. 2A and 6A-6C, portions of each fin structure 400 are removed from the device 300 to form source/drain recesses 708 at the operation 210. Each source/drain recess 708 is interposed between two adjacent dummy gate structures 600 along the first lateral direction and thus provides the space for the subsequent formation of a corresponding source/drain feature. In various embodiments, the source/drain recesses 708 are formed by performing an etching process, such as an anisotropic etching process, to remove portions of the ML interposed between the dummy gate structures. The etching process may be selective to remove the materials of the ML and the substrate and may be implemented using the dummy gate structures as an etch mask, for example.

Still referring to FIGS. 2A and 7A-8C, the first semiconductor layers 304 are replaced with sacrificial layer 720 at the operation 212. Replacing the first semiconductor layers 304 with the sacrificial layer 720 may reduce or prevent defects from forming on surfaces of the second semiconductor layers 306 adjacent to each corresponding first semiconductor layer 304 during subsequent annealing processes. In some instances, without replacing the first semiconductor layers 304, inadvertent diffusion of germanium atoms into the channel layers (i.e., the second semiconductor layers 306) may occur during the annealing process(es), potentially causing undesirable surface roughness at subsequent fabrication operations (e.g., gate replacement process). The sacrificial layers 720 described herein do not include germanium (or other semiconductor materials) and may thus mitigate or prevent formation of undesirable surface roughness in the channel layers. In various embodiments, the sacrificial layers 720 include a dielectric material and are therefore alternatively referred to as dielectric sacrificial layers 720.

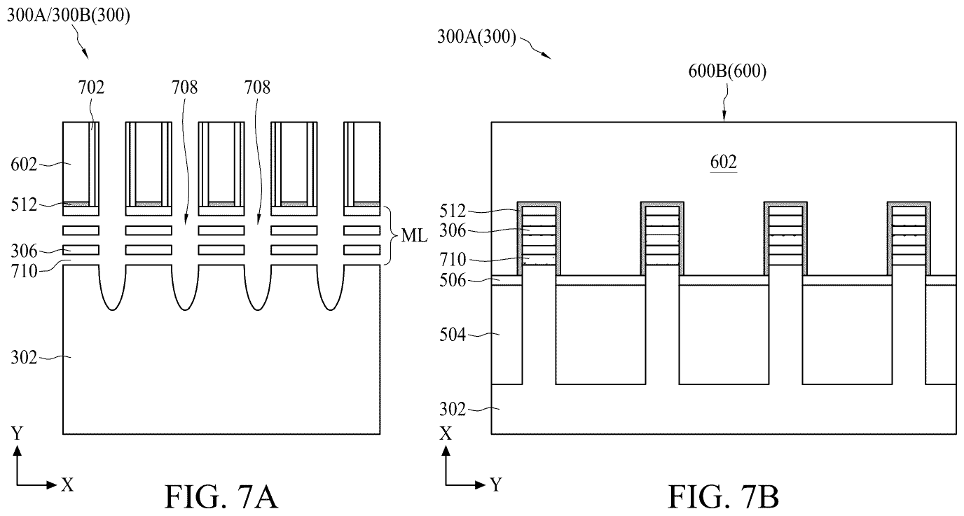

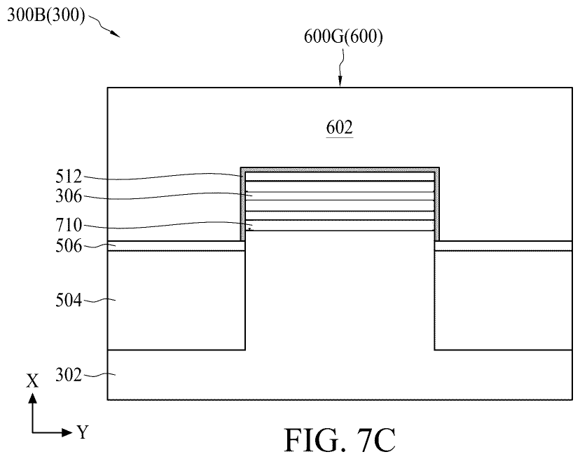

Referring to FIGS. 7A-7C, the first semiconductor layers 304 are removed from the ML, resulting in openings 710 interleaved (or alternately arranged) with the second semiconductor layers 306 along the vertical direction. As depicted herein, the openings 710 adjoin with adjacent source/drain recesses 708 along the first lateral direction. In some embodiments, the openings 710 are formed by performing an etching process that selectively removes the first semiconductor layers 304 without removing, or substantially removing the second semiconductor layers 306. The etching process may be a dry etching process or a wet etching process. In some embodiments, the etching process may be an isotropic etching process. For embodiments in which the first semiconductor layers 304 include silicon germanium, the etching process at the operation 212 may be implemented as a wet etching process utilizing a phosphoric acid (H₃PO₄)-containing solution as an etchant. In some embodiments, the etching process at the operation 212 may be implemented as a dry etching process utilizing one or more halogen-containing etchant, such as F₂, HF, NH₃, other suitable etchants, or combinations thereof.

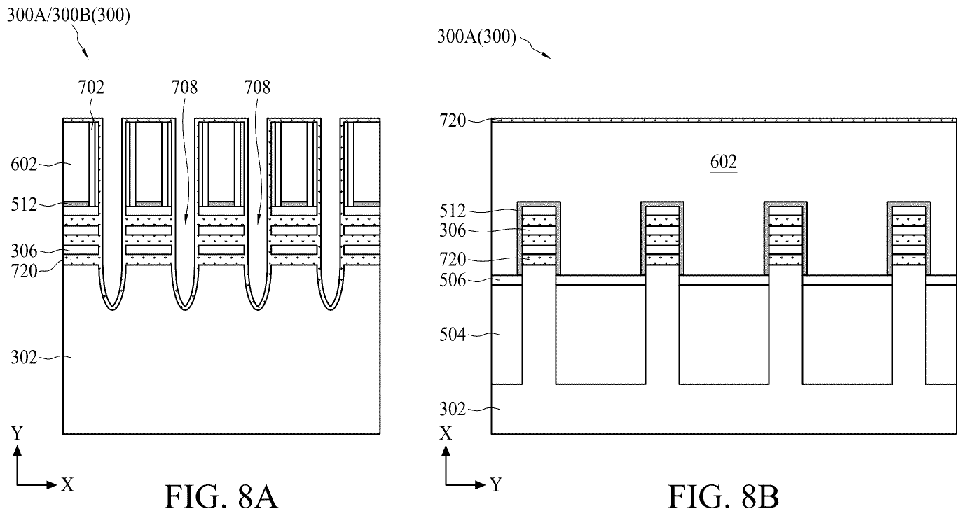

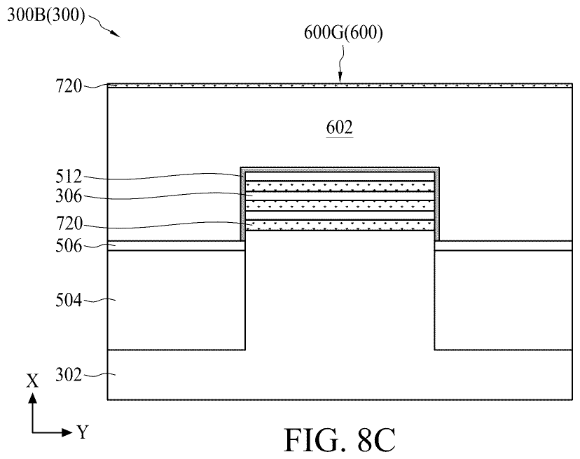

Subsequently, referring to FIGS. 8A-8C, the sacrificial layers 720 are formed in the openings 710. The sacrificial layers 720 include any suitable material that exhibits relatively high etching selectivity to the second semiconductor layers 306 and other subsequently formed features surrounding them. In some embodiments, the sacrificial layers 720 include a suitable dielectric material having a combination of silicon, oxygen, carbon, and nitrogen. For example, the sacrificial layers 720 may include silicon oxide, silicon nitride, silicon oxynitride, silicon carbonitride, silicon oxycarbonitride, silicon oxycarbide, other suitable dielectric materials, or combinations thereof. In this regard, the sacrificial layers 720 may be referred to as dielectric (e.g., oxide, nitride, etc.) interposers as they are interposed between adjacent channel layers (i.e., second semiconductor layers 306). In the present embodiments, the sacrificial layers 720 include an oxide (e.g., silicon oxide) at a first amount and a non-oxide material at a second amount less than the first amount. For example, at least about 90% of the sacrificial layers 720 by atomic mass is silicon oxide, and less than about 10% of the sacrificial layers 720 by atomic mass may include one or more of silicon nitride, silicon carbide, and hydrogen. Accordingly, the sacrificial layers 720 may be referred to as oxide interposers 720 or oxide layers 720.

The sacrificial layers 720 may be deposited as a blanket layer over the device 300, including over the dummy gate structures 600 and the gate spacers 702, by any suitable deposition process, such as CVD, ALD, the like, or combinations thereof. In some instances, the deposition of the sacrificial layers 720 may be controlled to ensure that the openings 710 are completely filled. Such a deposition process may cause excess oxide material to form over the dummy gate structures 600 and in the source/drain recesses 708, as depicted in FIG. 8A.

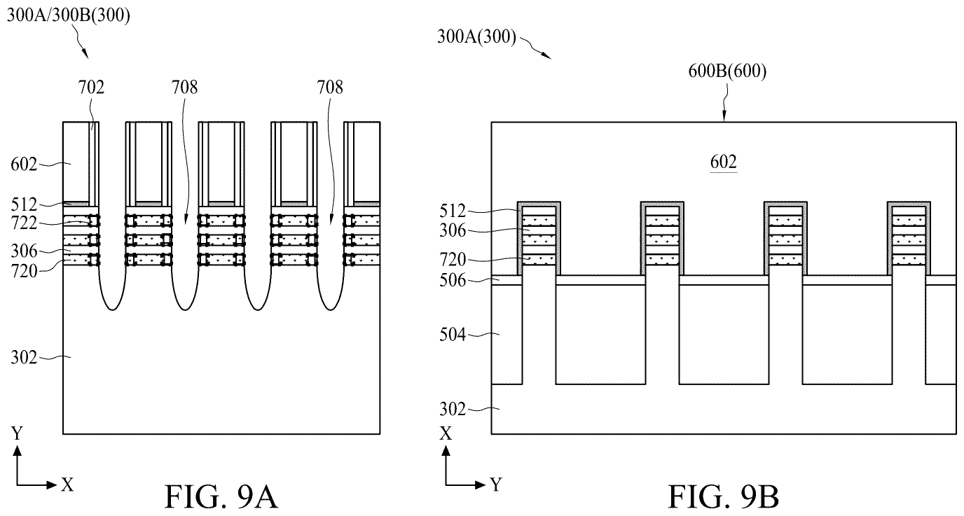

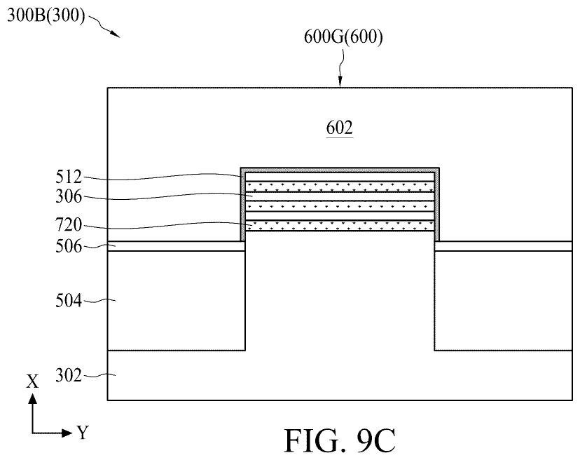

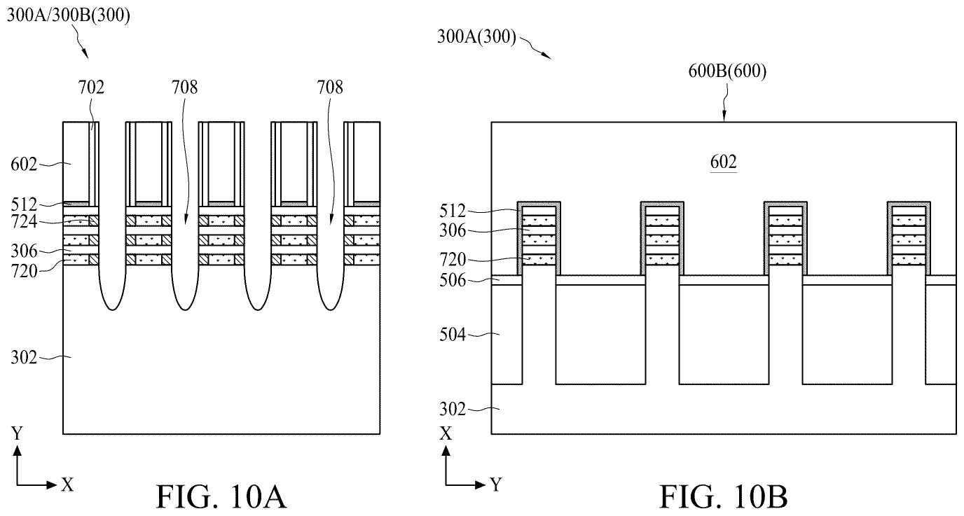

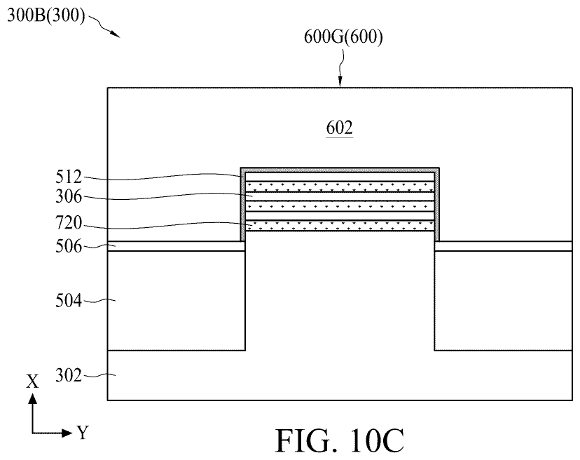

Referring to FIGS. 2A and 9A-10C, inner spacers are formed in the device 300 by replacing end portions of each sacrificial layer 720 exposed in the source/drain recesses 708 at the operation 214. FIGS. 9A-9C describe embodiments in which inner spacers 722 are formed, and FIGS. 10A-10C describe alternative embodiments in which inner spacers 724 are formed, where the inner spacers 724 differ from the inner spacers 722 in composition. In some embodiments, the inner spacers 722 and the inner spacers 724 each include a combination of silicon, oxygen, carbon, and nitrogen. For example, the inner spacers 722 and 724 may each include silicon oxide, silicon nitride, silicon oxynitride, silicon carbonitride, silicon oxycarbonitride, silicon oxycarbide, other suitable dielectric materials, or combinations thereof. However, the relative amounts of the different elements in the inner spacers 722 and 724 may differ.

For example, in the present embodiments, the inner spacers 722 include a greater amount of an oxide (e.g., silicon oxide) than a nitride (e.g., silicon nitride), and the inner spacers 724 include a greater amount of a nitride (e.g., silicon nitride) than an oxide (e.g., silicon oxide). In some embodiments, the inner spacers 722 include an oxide as a major component, and the inner spacers 724 include a nitride as a major component. In the present disclosure, “a major component” may refer to a component that is of at least about 90% of the composition by atomic mass. In this regard, the inner spacers 722 exhibit relatively low etching selectivity (or substantially no etching selectivity) to the sacrificial layers 720 as they both include, as a major component, an oxide (e.g., silicon oxide), while the inner spacers 724 exhibit relatively high etching selectivity to the sacrificial layers 720. In other words, as will be described in detail below, the inner spacers 722 may be removed concurrently with the sacrificial layers 720 during a subsequent etching process, while the inner spacers 724 may remain intact, or substantially intact, when the sacrificial layers 720 are removed during the subsequent etching process.

In some embodiments, forming the inner spacers 722/724 includes performing an etching process (alternatively referred to as an etch-back process) to remove portions of the sacrificial layers 720 formed over the dummy gate structures 600, the gate spacers 702, and the source/drain recesses 708, such that sidewalls of the second semiconductor layers 306 and end portions of the etched sacrificial layers 720 are exposed in the source/drain recesses 708. Subsequently, the end portions of the sacrificial layers 720 are further etched back from the sidewalls of the second semiconductor layers 306. Such etch-back process selectively removes the sacrificial layers 720 without removing, or substantially removing, portions of the second semiconductor layers 306, the substrate 302, the gate spacers 702, and other surrounding features. In some embodiments, the etch-back process is implemented until a desired etch-back distance is achieved, resulting in the alignment of the etched sacrificial layers 720 with the dummy gate structures 600 (i.e., the dummy gate electrode layer 602).

Subsequently, still referring to FIGS. 9A-10C, the inner spacers 722/724 are formed on the etched end portions of the sacrificial layers 720 in the source/drain recesses 708. The inner spacers 722/724 may be formed by depositing one or more layers of dielectric materials described herein by any suitable method, such as CVD, ALD, physical vapor deposition (PVD), other suitable methods, or combinations thereof. The dielectric material(s) may then be etched by a suitable etching process (e.g., an anisotropic dry etching process) to remove excess dielectric material(s) from the sidewalls of second semiconductor layers 306, the gate spacers 702, and the top surface of the substrate 302. Unless otherwise noted, the subsequent operations of the method 200 are described using the inner spacers 722 for purposes of illustration.

Subsequently, referring to FIGS. 2A and 11A-11E, the source/drain features 802 are formed in the source/drain recesses 708 over the inner spacers 722 at the operation 216. The source/drain features 802 may include any suitable semiconductor materials. For embodiments in which the resulting transistor is an n-type device, the source/drain features 802 may include silicon doped with an n-type dopant such as phosphorus (P), arsenic (As), antimony (Sb), other n-type dopants, or combinations thereof. For embodiments in which the resulting transistor is an p-type device, the source/drain features 802 may include silicon germanium doped with an n-type dopant such as boron (B), aluminum (Al), indium (In), gallium (Ga), other p-type dopants, or combinations thereof.

In some embodiments, sidewalls of the source/drain features 802 are aligned with the sidewalls of the inner spacers 704 and the second semiconductor layers 306 along the vertical direction. The source/drain features 802 may be formed using an epitaxial layer growth process on exposed ends of each of the second semiconductor layers 306 and the exposed substrate 302. For example, the growth process may include a selective epitaxial growth (SEG) process, CVD deposition techniques (e.g., vapor-phase epitaxy (VPE) and/or ultra-high vacuum CVD (UHV-CVD)), molecular beam epitaxy, other suitable epitaxial processes, or combinations thereof. In some embodiments, bottom surfaces of the source/drain features 802 are lower than a top surface of the isolation structures 504. In some embodiments, the dopants are introduced in-situ during the growth process. Alternatively, an implantation process may be performed to introduce the dopants after the growth process is implemented. After forming the source/drain features 802, an annealing process is performed to activate the dopants.

In some embodiments, referring to FIG. 11C, a dielectric layer 804 is formed at a bottom portion of each of the source/drain recesses 708 before forming the corresponding source/drain feature 802. The dielectric layer 804 may include any suitable dielectric material, such as silicon oxide, silicon nitride, silicon oxynitride, silicon carbonitride, silicon oxycarbonitride, silicon oxycarbide, other suitable dielectric materials, or combinations thereof. The dielectric layer 804 may be formed by depositing a dielectric material in the source/drain recesses 708 by any suitable process, such as CVD, ALD, other processes, or combinations thereof. The dielectric material is subsequently etched back to expose a top portion of the source/drain recesses 708, leaving the dielectric layer 804 on the bottom portion of the source/drain recesses 708. The dielectric material may be etched by any suitable process, such as a dry etching, a wet etching, or combination thereof. The etching process may be controlled to ensure that a sufficient amount of the dielectric layer 804 remains in the source/drain recesses 708 before forming the source/drain features 802. In some embodiments, the dielectric layer 804 is configured to reduce or prevent current leakage between bottom portions of adjacent source/drain features 802. In some embodiments, the dielectric layer 804 is omitted from the device 300. For illustrative purposes, the dielectric layer 804 is omitted from the device 300 in the subsequent figures of the present disclosure.

Referring to FIGS. 2A, 2B, and 12A-23C collectively, fin isolation structures 850A, 850B, 850C, and 850C (collectively referred to as fin isolation structures 850) are formed in the device 300 at the operation 218. In some embodiments, referring to FIG. 2B, the operation 218 may be implemented by sub-operations 252-266.

In brief overview, the operation 218 may begin with sub-operation 252 of forming an interlayer dielectric layer (ILD) over the source/drain features. Next, the operation 218 proceeds to sub-operation 254 of forming a hard mask over the ILD layer. The operation 218 proceeds to sub-operation 256 of patterning the hard mask to expose portions of the dummy gate structures. The operation 218 proceeds to sub-operation 258 of performing a first etching process to remove the exposed portions of the dummy gate structures. The operation 218 proceeds to sub-operation 260 of performing a second etching process to remove the sacrificial layers. The operation 218 proceeds to sub-operation 262 of performing a third etching process to remove exposed second semiconductor layers, resulting in fin cut trenches. The operation 218 proceeds to sub-operation 264 of depositing a dielectric layer in the fin cut trenches. The operation 218 proceeds to sub-operation 266 of planarizing the dielectric layer to form the fin isolation structures.

Referring to FIGS. 2B and 12A-12C, an ILD layer 806 is formed over the source/drain features 802 at the sub-operation 252. In some embodiments, the ILD layer 806 includes an oxide, such as silicon oxide, a low-k dielectric material, such as PSG, BSG, BPSG, USG, other suitable dielectric materials, or combinations thereof. The ILD layer 806 may be deposited by any suitable method, such as CVD, PECVD, FCVD, other suitable methods, or combinations thereof. A planarization process, such as a CMP process, may be performed such that a top surface for the ILD layer 806 may be leveled (or substantially coplanar) with the dummy gate structures 600. In some embodiments, performing the planarization process removes the patterned hard mask from the dummy gate structures 600.

In the present embodiments, the ILD layer 806 includes an oxide, such as silicon oxide, which is substantially similar to or the same as the composition of the sacrificial layers 720 and the inner spacers 722. As such, in order to protect the ILD layer 806 from being inadvertently removed during the subsequent etching processes, a protective capping layer including a dielectric material that is different from that of the ILD layer 806 is formed over the ILD layer 806. For example, a dielectric cap 808 (alternatively referred to as a hard mask 808) including a nitride, such as silicon nitride, may be formed over the ILD layer 806 and between the gate spacers 702. Forming the dielectric cap 808 may include recessing or etching back a top portion of the ILD layer 806 such that its top surface is below that of the dummy gate structures 600. Subsequently, a dielectric material (e.g., a nitride) may be deposited over the device 300 and planarized to form the dielectric cap 808 having a top surface substantially leveled with the dummy gate structures 600.

Still referring to FIGS. 2B and 12A-12C, a hard mask 730 is formed over the device 300 at the sub-operation 254. In various embodiments, the hard mask 730 includes a dielectric material having a composition different from the underlying dummy gate structures 600, for example, such that the hard mask 730 may be patterned to form an etch mask for etching at least the dummy gate structures 600 during the subsequent operations. In some embodiments, the hard mask 730 includes a nitride, such as silicon nitride. The hard mask 730 may be formed by performing a deposition process, such as CVD, ALD, PVD, other suitable processes, or combinations thereof.

Referring to FIGS. 2B and 13A-13C, the hard mask 730 is patterned to expose portions of the underlying dummy gate structures 600 at the sub-operation 256. A masking element ME is first formed over the hard mask 730. In some embodiments, the ME includes a multilayer structure comprising a bottom layer 832, a middle layer 834 over the bottom layer 832, and a top layer 836 over the middle layer 834. The bottom layer 832 may include a carbon-containing bottom anti-reflective coating (BARC) configured to reduce reflection of the underlying features, such as the dummy gate structures 600, during a subsequent photolithography process for patterning the hard mask 730. The middle layer 834 may include a silicon-containing dielectric material. In some examples, the bottom layer 832 may include a spin-on carbon (SOC) layer, and the middle layer 834 may include a spin-on glass (SOG) layer. The top layer 836 includes a photoresist material that is capable of undergoing photochemical changes in response to light exposure (e.g., UV exposure, extreme UV (EUV) exposure, etc.).

Generally, photolithography techniques utilize the photoresist material of the top layer 836 that is deposited, irradiated (exposed), and developed to portions of the top layer 836, as depicted in FIGS. 13A-13C, resulting in a patterned top layer 836. The remaining portions of the patterned top layer 836 protect the underlying material, such as the middle layer 834, the bottom layer 832, and the hard mask 730 from the subsequent etching processes.

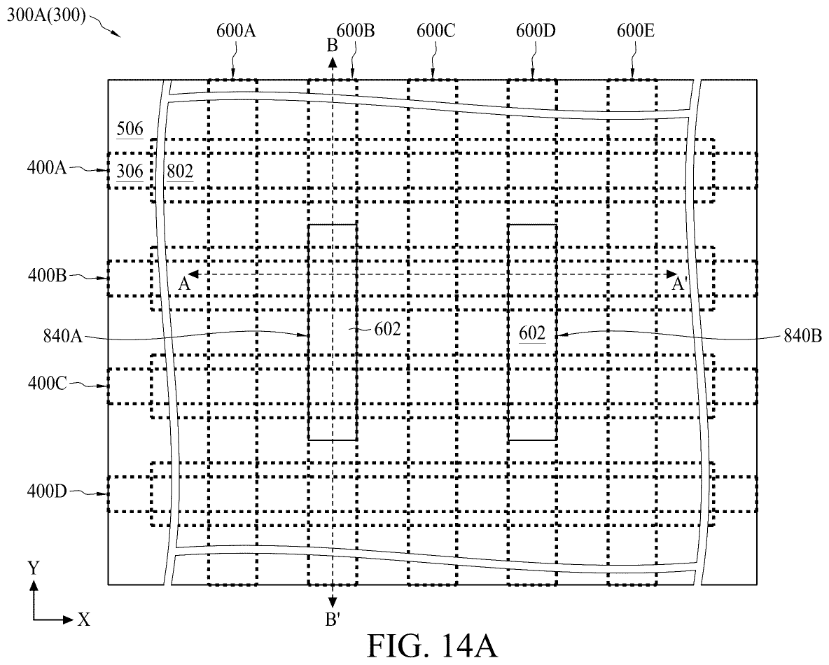

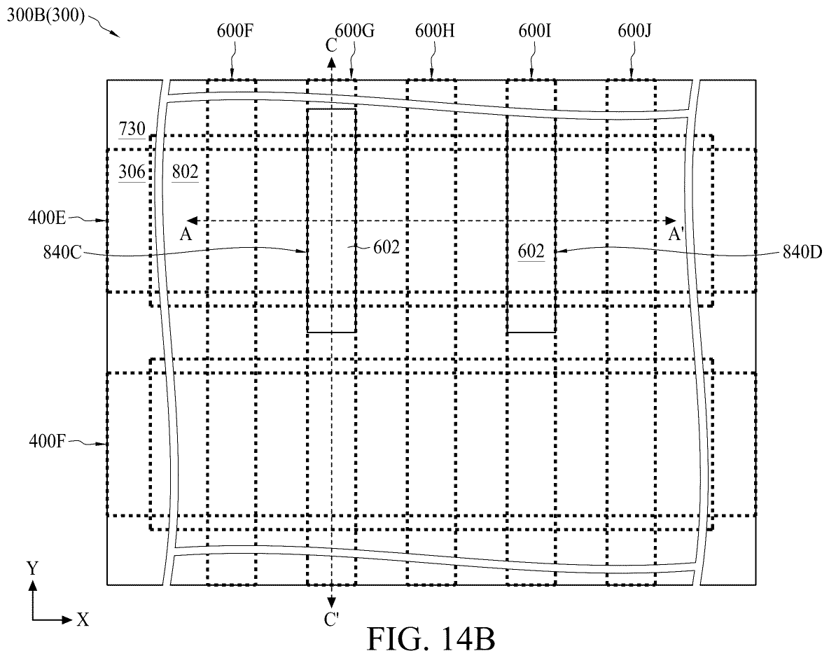

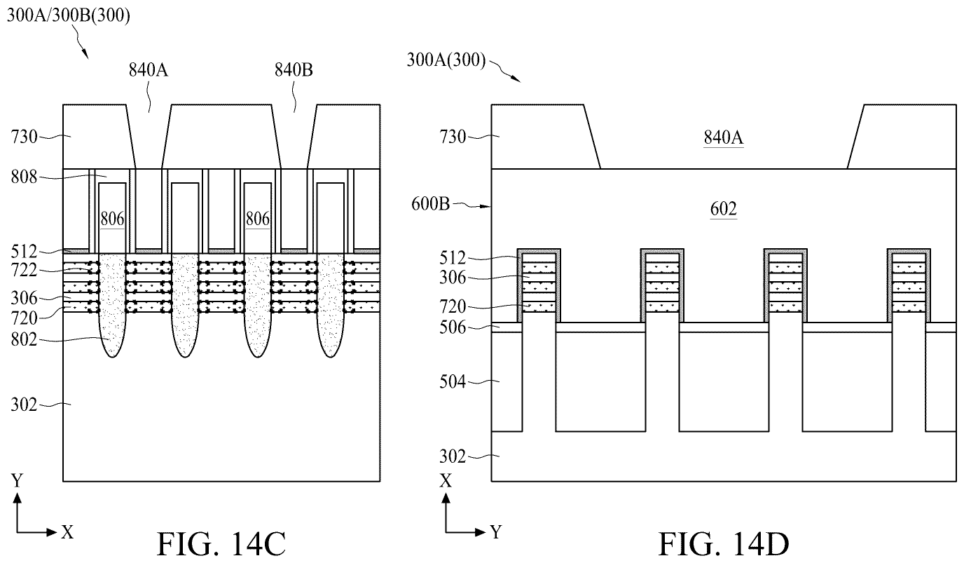

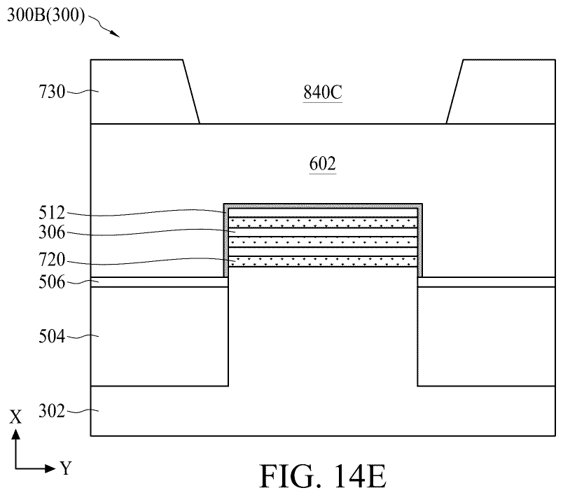

Referring to FIGS. 14A-14E, the patterned top layer 836 may then be used as an etch mask to pattern the underlying middle layer 834 and the bottom layer 832 of the ME using the patterned top layer 836 as an etch mask, resulting in a patterned ME (not depicted). The middle layer 834 and the bottom layer 832 may be etched by any suitable etching process, such as a dry etching process, a wet etching process, or the like. For example, the middle layer 834 may be etched by a dry etching process utilizing a plasma-based etchant generated from a carbon-hydrogen-and/or-fluorine-containing gas, such as CH₄, CH₃F, CH₂F₂, CHF₃, CF₄, other suitable gasses, or combinations thereof. Other gases such as N₂ or Ar may be used as a dilution gas. The bottom layer 832 may be etched by a dry etching process utilizing a plasma-based etchant generated from an oxygen-containing gas, such as O₂, CO₂, CO, and SO₂, other suitable gasses, or combinations thereof, resulting in the patterned ME.

Subsequently, the patterned ME is used as an etch mask to remove portions of the hard mask 730, resulting in a patterned hard mask 730 as depicted in FIGS. 14A-14E. The hard mask 730 may be etched using a suitable process, such as a dry etching process or a wet etching process. In some examples, the hard mask 730 may be etched using a plasma-based etchant similar to that used for etching the middle layer 834 described above.

The patterned hard mask 730 exposes portions of one or more of the dummy gate structures 600 in trenches (or openings) 840A, 840B, 840C, and 840D (collectively referred to as trenches 840). Specifically, referring to FIGS. 14A and 14D (the device 300A), the patterned hard mask 730 exposes a portion of the dummy gate structure 600B in a trench 840A and a portion of the dummy gate structure 600D in a trench 840B. Similarly, referring to FIGS. 14B and 14E (the device 300B), the patterned hard mask 730 exposes a portion of the dummy gate structure 600G in a trench 840C and a portion of the dummy gate structure 600I in a trench 840D. After patterning the hard mask 730, the patterned ME may be removed by a suitable method, including, for example, an etching process, a plasma ashing process, a resist stripping process, or combinations thereof.

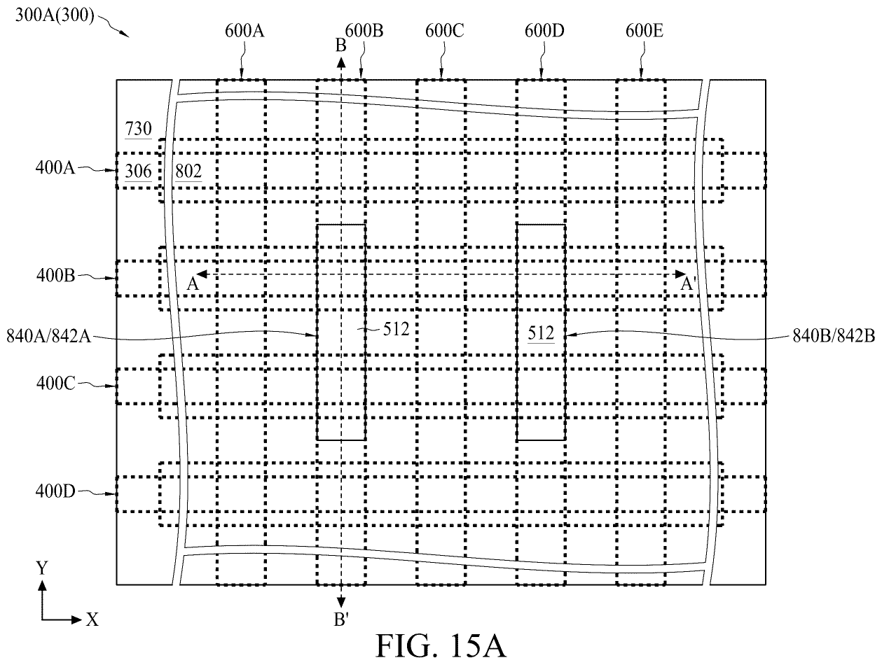

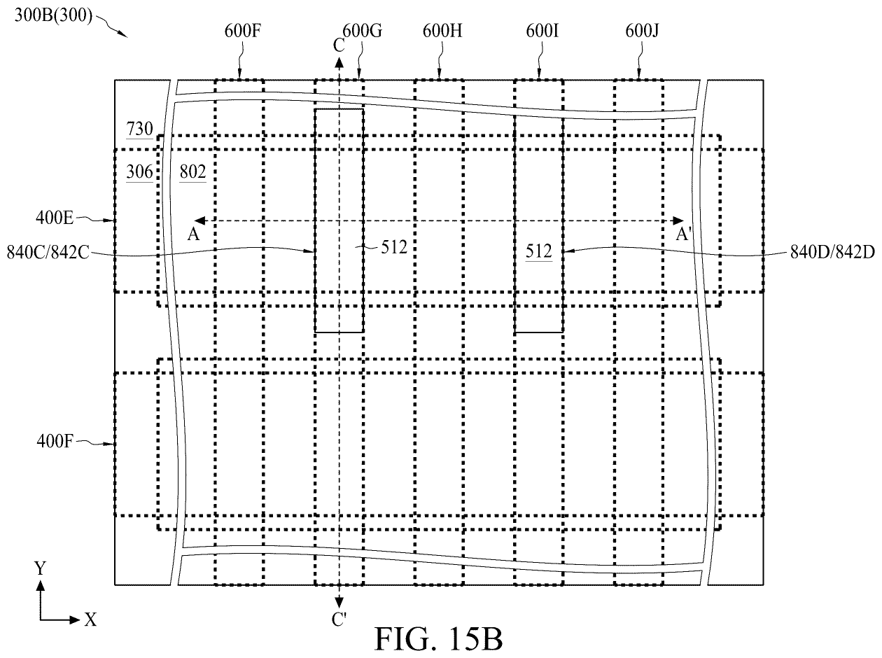

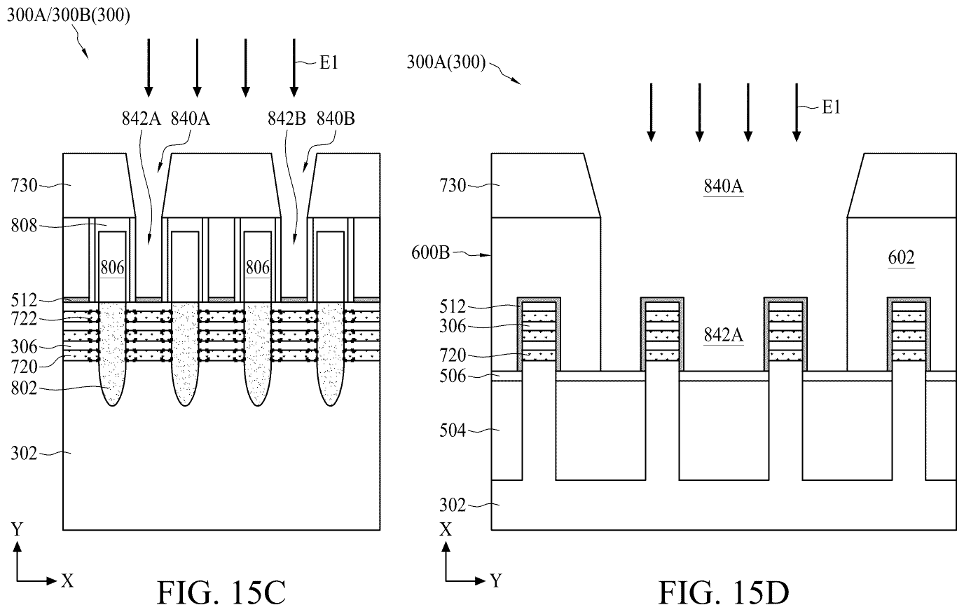

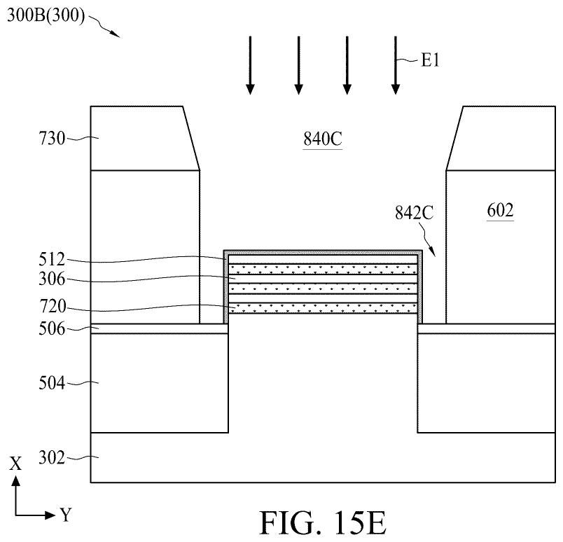

Referring to FIGS. 2B and 15A-15E, a first etching process E1 is performed to remove portions of the dummy gate structures 600 exposed by the patterned hard mask 730 at the sub-operation 258. In the present embodiments, the first etching process E1 is configured as a directional (e.g., substantially vertical) or anisotropic etching process for removing the exposed portions of the dummy gate structures 600 between the corresponding gate spacers 702.

In some embodiments, the first etching process E1 is implemented as a dry etching process (e.g., an RIE process) utilizing a plasma-based etchant. In the present embodiments, the plasma-based etchant used during the first etching process E1 is configured to selectively remove the dummy gate electrode layer 602 (e.g., polysilicon) without removing, or substantially removing, the oxide layer 512, the gate spacers 702, the second semiconductor layers 306, the sacrificial layers 720, and the inner spacers 722 (or 724). The plasma-based etchant may be generated from a halogen-containing gas such as a chlorine-containing gas, a bromine-containing gas, a fluorine-containing gas, other suitable gases, or combinations thereof. Examples of the suitable gases include Cl₂, HBr, BCl₃, CF₄, other suitable gases, or combinations thereof. In some examples, additional gases such as Ar, O₂, N₂, CO₂, SO₂, CO, CH₄, SiCl₄, other suitable gases, or combinations thereof, may be used during the first etching process E1. Other suitable gases may also be applicable for utilization during the first etching process E1. In some examples, the first etching process E1 may be performed in etching tools equipped with inductively-coupled plasma (ICP), capacitively-coupled plasma (CCP), or dipole antenna coil for providing source power that forms the plasma and for providing bias power to accelerate the plasma to achieve directional etching.

As depicted herein, performing the first etching process E1 forms trenches (or openings) 842A, 842B, 842C, and 842D (collectively referred to as trenches 842) that extend from and are connected to the trenches 840A, 840B, 840C, and 840D, respectively. In some embodiments, referring to FIGS. 15A and 15B, each trench 842 extends past edges of the corresponding fin structure(s) 400 along the second lateral direction.

Referring to FIGS. 15A, 15B, 15D, and 15E, the trenches 842 (and the trenches 840) are configured to only expose a portion of a given dummy gate structure 600 over a certain number of the fin structures 400 along the second lateral direction, while portions of the dummy gate structure 600 adjacent to the trenches 842 remaining over other fin structures 400. For example, referring to FIGS. 15A and 15D, the trench 842A exposes a portion of the dummy gate structure 600B over the fin structures 400B and 400C, and the trench 842B exposes a portion of the dummy gate structure 600D over the fin structures 400B and 400C. Similarly, referring to FIGS. 15B and 15E, the trench 842C exposes a portion of the dummy gate structure 600G over the fin structure 400E, and the trench 842D exposes a portion of the dummy gate structure 600I over the fin structure 400E.

Referring to FIGS. 2B and 16A-17C, a second etching process E2 is performed to remove the sacrificial layers 720 exposed in the trenches 842 at the sub-operation 260. In the present embodiments, the second etching process E2 is configured as a non-directional, isotropic etching process for removing the oxide layer 512 and the exposed portions of the sacrificial layers 720 in the trenches 842. In some embodiments, the second etching process E2 removes additional portions of the device 300, such as the inner spacers 722. As depicted herein, performing the second etching process E2 forms openings 844A, 844B, 844C, and 844D (collectively referred to as the openings 844) below the trenches 842A, 842B, 842C, and 842D, respectively.

In some embodiments, the second etching process E2 is implemented as a solvent-based, wet etching process utilizing a wet etchant (or a wet bath). Alternatively or additionally, the second etching process E2 may be implanted as a plasma-based, isotropic dry etching process utilizing a gas bath. In the present embodiments, the etchant used during the second etching process E2 is configured to selectively remove the oxide-containing components of the device 300 exposed in the trenches 842 without removing, or substantially removing, the second semiconductor layers 306, the sacrificial layers 720, and the second spacer layer 702B of the gate spacers 702. In this regard, referring to FIGS. 16A-17C collectively, the wet etchant is configured to selectively remove at least the oxide layer 512 and the sacrificial layers 720.

In some embodiments, referring to FIGS. 16A-16E, the second etching process E2 is configured to additionally remove at least portions of the inner spacers 722, which has a composition similar to or the same as that of the oxide layer 512 and the sacrificial layers 720. For example, the inner spacers 722 include, as a major component, an oxide (e.g., silicon oxide). Accordingly, the inner spacers 722 exhibit relatively low etching selectivity (or substantially no etching selectivity) to the oxide layer 512 and the sacrificial layers 720 and are therefore more susceptible to the chemical attack of the etchant implemented at the second etching process E2.

For example, referring to FIG. 16C, the trenches 842 each have a width W1 between the gate spacers 702 along the first lateral direction, and the second etching process E2 removes both the sacrificial layers 720 as well as the inner spacers 722, such that the openings 844 each extend a width W2 along the first lateral direction, where the width W2 is greater than the width W1. In this regard, a difference between the width W1 and the width W2 accounts for two times a width of each of the inner spacers 722. In some embodiments, the inner spacers 722 are partially removed such that some portions of the inner spacers 722 remain in the openings 844. Alternatively, the inner spacers 722 are completely removed such that the source/drain features 802 are exposed in the adjacent openings 844.

In contrast, referring to FIGS. 17A-17C, the second etching process E2 does not remove, or substantially remove, any portion of the inner spacers 724, which include, as a major component, a nitride (e.g., silicon nitride). In this regard, the inner spacers 274 exhibit relatively higher etching selectivity to the oxide layer 512 and the sacrificial layers 720 than the inner spacers 272. For example, referring to FIG. 17A, which is analogous to FIG. 16C, the trenches 842 each have the width W1 similar to that depicted in FIG. 16C, and the second etching process E2 removes only the sacrificial layers 720 but not the inner spacers 724, such that the openings 844 each extend a width W3 between the inner spacers 724 along the first lateral direction, where the width W3 is similar to or the same as the width W1.

For embodiments in which the second etching process E2 is implemented as a wet etching process, a wet etchant (or solvent-based etchant) such as dHF may be utilized. In some examples, the dHF may be diluted with water to a concentration of about 0.01× to about 0.1×. In some embodiments, optimal etching conditions for the second etching process E2 can be achieved by tuning the concentration of the dHF.

For embodiments in which the second etching process E2 is implemented as a plasma-based isotropic dry etching process, a plasma-based etchant including NH₃, HF, or a combination thereof, may be utilized. Other suitable gases may also be applicable for utilization during the second etching process E2. In some embodiments, after performing the dry etching process, one or more annealing process is performed at a temperature of above 100° C. to remove etching by-products, such as ammonium fluorosilicate. In some embodiments, optimal etching conditions for the second etching process E2 can be achieved by tuning a ratio of etchant HF/NH₃, where the ratio may range from about 0.1 to about 10 and a higher ratio generally leads to a lower etching selectivity to oxide (e.g., silicon oxide), and by controlling removal of etching by-product by tuning temperature and/or pressure, where a higher temperature and lower pressure generally leads to faster by-product removal rates and lower etching selectivity.). In some embodiments, the etchants are dissociated into radicals to enhance their reactivity by utilizing plasma coil in the etching tools.

In some embodiments, the second etching process E2 may include a combination of the wet etching process (e.g., using the dHF as an etchant) and the dry etching process (e.g., using the HF/NH₃ as an etchant) described herein and implemented with different etchant concentrations and compositions to maximize etching rate of the oxide layer 512 and the sacrificial layers 720, thereby ensuring complete removal of these materials from the device 300.

In the present embodiments, as described herein, both the isolation structure 504 and the ILD layer 806 may include an oxide (e.g., silicon oxide) as a major component. In this regard, the hard mask 506 is provided to protect the underlying isolation structures 504 and the dielectric cap 808 is configured to protect the underlying ILD layer 806 during the second etching process E2. Specifically, the hard mask 506 exhibits relatively higher etching selectivity to the sacrificial layers 720 (and the substrate 302) than the isolation structures 504 to the sacrificial layers 720. Furthermore, the dielectric cap 808 exhibits relatively higher etching selectivity to the sacrificial layers 270 (and the substrate 302) than the ILD layer 806 to the sacrificial layers 270.

Referring to FIGS. 2B and 18A-19C, a third etching process E3 is performed to remove the second semiconductor layer 306 remaining in the ML at the sub-operation 262, resulting in fin cut trenches 830. In the present embodiments, the third etching process E3 is configured as a directional (e.g., substantially vertical) or anisotropic etching process for removing the second semiconductor layers 306, bottom portions of the fin structures 400 (e.g., the fin structure 400B in FIGS. 18C and 19A), and top portions of the substrate 302 exposed in the trenches 840, the trenches 842, and the openings 844.

As depicted herein, performing the third etching process E3 forms trenches 846A, 846B, 846C, and 846D between the openings 844A, 844B, 844C, and 844D, respectively. In some embodiments, as depicted in FIGS. 18C and 19A, performing the third etching process E3 further extends the trenches 846 along the vertical direction, thereby removing the bottom portions of the fin structures 400. Still further, performing the third etching process E3 removes the top portions of the substrate 302 to form trenches 848A, 848B, 848C, and 848D, below the trenches 846A, 846B, 846C, and 846D, respectively. The trenches 840, 842, 846, 848 and openings 844 together form corresponding fin cut trenches 830A, 830B, 830C, and 830D (collectively referred to as the fin cut trenches 830). In this regard, referring to FIGS. 18A and 18B, each fin cut trench 830 vertically extends through a corresponding fin structure 400 and into the substrate 302, thereby separating (truncating or cutting) the fin structure 400 into multiple portions along the first lateral direction. Furthermore, sidewalls of each fin cut trench 830 are vertically aligned with sidewalls of a corresponding dummy gate structure 600 along the second lateral direction.

For embodiments in which performing the second etching process E2 selectively removes the inner spacers 722, referring to FIGS. 18C-18E, entire sidewalls of the trenches 846 expose the adjacent source/drain features 802. For embodiments in which performing the second etching process E2 does not remove, or substantially remove, the inner spacers 724, referring to FIGS. 19A-19C, the inner spacers 724 extend laterally from sidewalls of the adjacent source drain features 802 into the trenches 846.

In some embodiments, the third etching process E3 is implemented as a dry etching process utilizing a plasma-based etchant, similar to the first etching process E1. In some embodiments, the plasma-based etchant is configured to selectively remove silicon, which is included as a major component in the second semiconductor layers 306, the bottom portions of the fin structures 400, and the top portions of the substrate 302.

The plasma-based etchant may be generated from any suitable gas such as a chlorine-containing gas, a bromine-containing gas, other suitable gases, or combinations thereof. Examples of the suitable gases for the third etching process E3 may include HBr, Cl₂, BCl₃, CF₄, CHF₃, CH₂F₂, CHF₃, C₄F₆, other suitable gases, or combinations thereof, with addition of gases such as O₂ or CO₂. In some embodiments, passivation layers containing SiO or CH₄ are formed to protect the patterned hard mask 730 by using precursor gases such as SiCl₄, O₂, and HBr or CH₄, Ar, and N₂, respectively. Subsequently, one or more of the gases described herein are used to remove (or break through) the passivation layers in the etch front and continue to remove the second semiconductor layers 306 during the third etching process E3.

In some embodiments, referring to FIGS. 18C and 19A, the highly selective plasma ions provided during the third etching process E3 can deflect and scatter in an asymmetric manner, resulting in a portion of sidewalls of the trenches 846 to have a curved (or bowed) profile 845 extending outward along the first lateral direction from the substantially vertical sidewalls of the trench 842 in the top portion of the fin cut trench 830. Notably, without applying the selective etching process E3, the curved profile 845 may not be formed in the sidewalls of the fin cut trench 830.

In some examples, etching tools may utilize plasma generated by an ICP or a dipole antenna coil plasma source driven by an RF power generator using a frequency of about 13.56 MHz or about 27 MHz. Processing chamber of the etching tool may be operated at a pressure in a range of about 1 mTorr to about 200 mTorr and a temperature of about 20° C. to about 200° C. The RF power generator may be operated to provide source power between about 100 W to about 2500 W. In some embodiments, a pulse plasma etching process with a duty cycle in a range of about 5% to about 100% is implemented during the etching process E3. An RF bias power to a pedestal on which the device 300 is located is in a range of about 0 W to about 1200 W may be implemented.

In the depicted embodiments, referring to FIGS. 18D, 18E, 19B, and 19C, performing the third etching process E3 forms notches 849 at an etch front, i.e., bottom corners of the trenches 848, due to varying etch rates surrounding the stack of the second semiconductor layers 306. Specifically, due to the directional (e.g., substantially vertical) nature of the third etching process E3, top and edge portions of the second semiconductor layers 306 are removed at a higher rate than a center portion of the second semiconductor layers 306, resulting in the bottom corners of the trenches 848 to extend further into the substrate 302 than a center portion of the trenches 848, resulting in the notches 849. In this regard, a first one of the notches 849 extends along a first sidewall of the fin isolation structure 850 and a second one of the notches 849 extends along a second sidewall of the fin isolation structure 850 opposite to the first sidewall.

When the fin width of the fin structures 400 is less than a lower threshold value, such as less than about 20 nm, the notches 249 may merge with one another, and a separation distance between the notches 249 may be approximately zero. When the fin width of the fin structures 400 is between the lower threshold value and a higher threshold value, such as between about 20 nm, inclusive, and about 60 nm, inclusive, the notches 249 may begin to separate from one another along the first lateral direction. When the fin width of the fin structures 400 is greater than the higher threshold value, such as greater than about 60 nm, the notches 249 may be completely separated from one another along the first lateral direction. In other words, as the fin width increases, the separation distance between the notches 249 increases.

For example, referring to FIGS. 18D and 19B, centerlines of notches 849A, which correspond to the notches 849 in the fin structures 400 having the fin width W1, are separated by a distance D1 along the first lateral direction and, referring to FIGS. 18E and 19C, centerlines of notches 849B, which correspond to the notches 849 in the fin structures 400 having the fin width W2, are separated by a distance D2 along the first lateral direction. As the fin width W2 is greater than the fin width W1, the distance D2 is greater than the distance D1, according to the present embodiments.

In existing technologies, the oxide layer 512, the inner spacers 722, the sacrificial layers 720, and the substrate 302 are removed during a single etching process utilizing a non-selective etchant. For example, the non-selective etchant may include plasma generated from both a chlorine-containing gas and a fluorine-containing gas configured to remove the dummy gate electrode layer 602, the oxide layer 512, the sacrificial layers 720, the substrate 302, and the second semiconductor layers 306, for example. While such an approach is generally adequate, it is not entirely satisfactory in all aspects. For example, when a shift in the overlay of a photolithography mask (hereafter referred to as an overlay shift or pattern shift) inadvertently occurs during the patterning of the hard mask 730 at the sub-operation 256, one or more of the trenches 840 may be vertically misaligned with the underlying dummy gate structure 600, subsequently causing partial removal of and/or defects in the adjacent components when the non-selective etching process is implemented. For example, the gate spacer 702 and the ILD layer 806 may be inadvertently removed, and, in some server cases, such misalignment could lead to damages in the adjacent source/drain features 802, resulting in poor device performance.

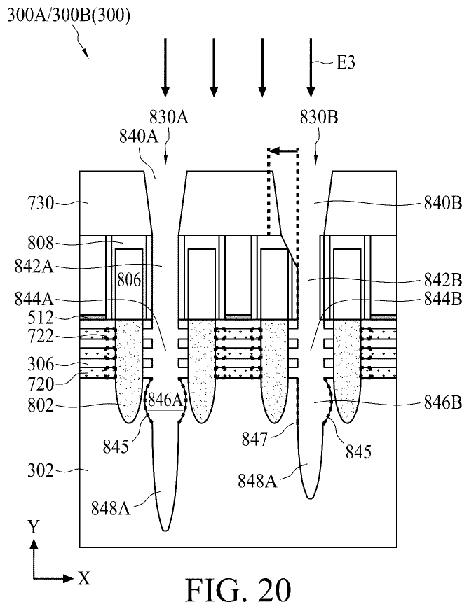

The present disclosure provides methods of implementing two selective etching processes to separately remove the oxide-containing components, including the oxide layer 512 and the sacrificial layers 720, and the silicon-containing components, including the second semiconductor layers 306 and the substrate 302. Specifically, the second etching process E2 is implemented using a non-directional, isotropic wet or dry etching process to selectively remove he oxide-containing components, and the third etching process E3 is implemented using a directional, anisotropic dry etching process to selectively remove the silicon-containing components. In this regard, should an overlay shift occur during the patterning of the hard mask 730, as indicated by the arrow shown in FIG. 20, applying the second etching process E2 substantially removes only the oxide layer 512 and the sacrificial layers 720 (and the inner spacers 722, if present), and applying the third etching process E3 removes only the portions of the second semiconductor layers 306 and the substrate 302 exposed in the trench 842 (e.g., the trench 842B), without substantially removing the adjacent source/drain feature 802. As a result, self-alignment of the fin cut trench 830 may be achieved and inadvertent damages to the source/drain features 802 may be reduced or avoided. In some examples, as depicted herein, the overlay shift may cause the directional third etching process E3 to form a substantially vertical profile 847 in a first sidewall of the trench 846 (e.g., the trench 846B) instead of the curved (or bowed) profile 845 (also see FIGS. 18C and 19A), which is in a second sidewall of the trench 846 opposing the first sidewall, leading to an asymmetric sidewall profile in the trench 846. In contrast, in the absence of any overlay shift, both sidewalls of the trench 846 include the curved profiles 845 as a result of applying the selective plasma-based etchant during the third etching process E3.

Referring to FIGS. 2B and 21A-21C, at least one dielectric layer is deposited in each fin cut trench 830 at the sub-operation 264. In the depicted embodiments, a first dielectric layer 852 (alternatively referred to as a dielectric liner 852) is first deposited in the fin cut trenches 830 and a second dielectric layer 854 (alternatively referred to as a dielectric filler 854) is deposited over the first dielectric layer 852 to fill the fin cut trenches 830.

In some embodiments, the first dielectric layer 852 and the second dielectric layer 854 each include a suitable dielectric material having various amounts of silicon, oxygen, carbon, and nitrogen. For example, the first dielectric layer 852 and the second dielectric layer 854 may each include silicon oxide, silicon nitride, silicon oxynitride, silicon carbonitride, silicon oxycarbonitride, silicon oxycarbide, other suitable materials, combinations thereof. In the present embodiments, the first dielectric layer 852 and the second dielectric layer 854 have different compositions and different dielectric constants (i.e., different k values). Furthermore, in some embodiments, the first dielectric layer 852 includes a dielectric material configured to accommodate the formation (e.g., by establishing a more uniform interface between different materials) of the second dielectric layer 854 in the fin cut trenches 830. In one such example, the first dielectric layer 852 may include silicon oxide and the second dielectric layer 854 may include silicon nitride, where the silicon oxide in the first dielectric layer 852 serves to provide a more uniform interface between the second dielectric layer 854 and the underlying material, such as silicon in the substrate 302. In some embodiments, composition and volume of the first dielectric layer 852 and the second dielectric layer 854 are respectively adjusted to tune the overall dielectric constant of the resulting fin isolation structure to a desired value. Additional dielectric layers may be formed in the fin cut trenches 830 before forming the first dielectric layer 852, between the first dielectric layer 852 and the second dielectric layer 854, and/or over the second dielectric layer 854.

The first dielectric layer 852 may be deposited by a conformal process, such as ALD, CVD, other suitable processes, or combinations thereof in the fin cut trenches 830. Subsequently, the second dielectric layer 854 may be deposited as a blanket layer over the first dielectric layer 852, thereby filling the fin cut trenches 830. For example, the second dielectric layer 854 may be deposited by ALD, CVD, FCVD, other suitable processes, or combinations thereof. As depicted herein, portions of the first dielectric layer 852 and the second dielectric layer 854 are formed over a top surface of the patterned hard mask 730.

Subsequently, referring to FIGS. 2B and 22A-23C, the first dielectric layer 852 and the second dielectric layer 854 are planarized to form fin isolation structures 850 at the sub-operation 266. The first dielectric layer 852 and the second dielectric layer 854 may be planarized using any suitable process, such as a CMP process, resulting in the fin isolation structures 850A, 850B, 850C, and 850D in the fin cut trenches 830A, 830B, 830D, and 830D, respectively. In some embodiments, planarizing the first dielectric layer 852 and the second dielectric layer 854 also removes the patterned hard mask 730 from the device 300, thereby exposing a top surface of the dummy gate electrode layer 602 of the dummy gate structures 600.

As depicted in FIG. 22C, due to the removal of the inner spacers 722 by the second etching process E2, portions of each fin isolation structure 850 extend along the first lateral direction to contact a sidewall of an adjacent source/drain feature 802. Such portions, defined by the width W2 of FIG. 16C, are referred to as lateral protrusions 856 that extend beyond a sidewall of an upper portion of the fin isolation structure 850 between the gate spacers 702, defined by the width W1 of FIG. 16C. In this regard, a first sidewall of the depicted source/drain feature 802 directly contacts a set of the inner spacers 722 and a second sidewall of the source/drain feature 802 directly contacts a set of the lateral protrusion 856 of the fin isolation structures 850. In contrast, as depicted in FIG. 23A, since the inner spacers 724 are not removed by the second etching process E2, the inner spacers 724 each extend between a sidewall of each fin isolation structure 850 and a sidewall of an adjacent source/drain feature 802. In this regard, a first sidewall of the depicted source/drain feature 802 directly contacts a first set of the inner spacers 724 and a second sidewall of the source/drain feature 802 directly contacts a second set of the inner spacers 724. In other words, the source/drain feature 802 is free of contact with the fin isolation structure 850.

In various embodiments, each fin isolation structure 850 functions as a CPODE structure that truncates the fin structure 400 (as well as the overlaying components of the device 300) with a dielectric feature, thereby electrically isolating devices (e.g., transistors) formed adjacent to one another along the fin structure 400. Thus, the fin isolation structure 850 provides at the benefit of reducing or eliminating leakage current through the adjacent active regions (e.g., the source/drain features 802 and/or the substrate 302). As depicted herein, the fin isolation structure 850 extends vertically into the substrate 302 to ensure isolation between laterally adjacent devices. Furthermore, since each fin isolation structure 850 is formed to replace a portion of a corresponding dummy gate structure 600, the scaling of the gate pitch of the device 300 is maintained.

In the present embodiments, by implementing a multistep etching scheme (i.e., the first etching process E1, the second etching process E2, and the third etching process E3), the fin isolation structures 850 may be formed in a self-aligned manner, thereby reducing or eliminating structural damages to the source/drain features 802 that can otherwise be caused by inadvertent overlay shift during the patterning process. In many instances, the methods of forming the fin isolation structures 850 are applicable when oxide-based sacrificial layers are utilized in the fabrication of GAA devices, which are designed to reduce surface roughness between channel layers and active gate structures for improved device performance.

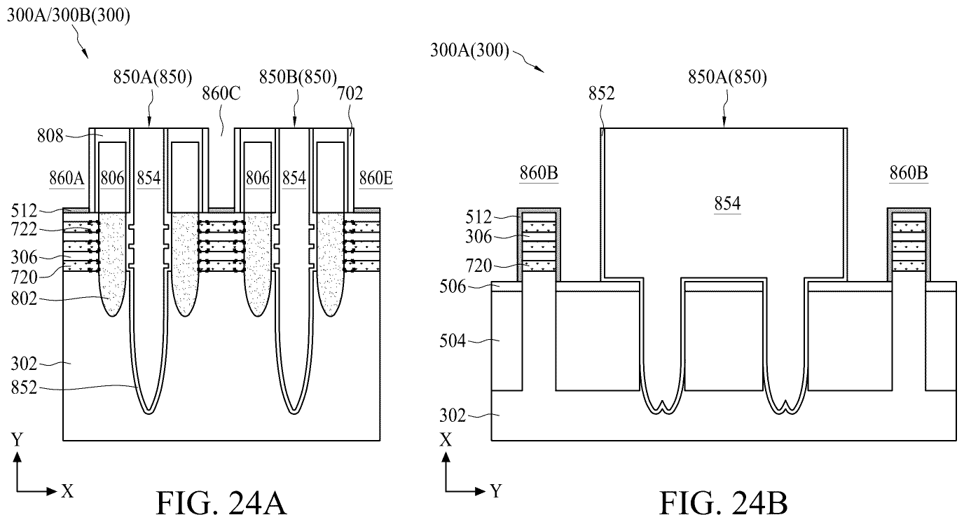

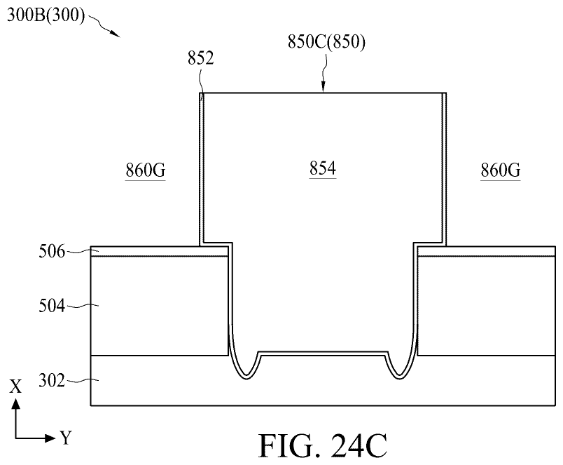

After completing the fabrication of the fin isolation structures 850 at the operation 218, the method 200 continues with the operation 220 as depicted in FIG. 2A. Referring to FIGS. 24A-24C, the dummy gate structures 600 are removed from the device 300 to form gate trenches 860 at the operation 220. As depicted herein, the dummy gate structures 600A-600E are removed to form the gate trenches 860A, 860B, 860C, 860D (not depicted herein), and 860E, respectively, in the device 300A, and the dummy gate structures 600F-600J are removed to form the gate trenches 860F (not depicted herein), 860G, 860H (not depicted herein), 860I (not depicted herein), and 860J (not depicted herein), respectively, in the device 300B. The gate trenches 860A-860J are collectively referred to as the gate trenches 860.

The dummy gate structures 600 may be removed by performing an etching process, such as a dry etching process, a wet etching process, other suitable processes, or combinations thereof. In various embodiments, the etching process is implemented using an etchant configured to remove the dummy gate electrode layer 602 that includes polysilicon, for example, without removing, or substantially removing, other components of the device 300, such as the hard mask 506, the oxide layer 512, the gate spacers 702, the dielectric cap 808, and the topmost second semiconductor layer 306. For example, the etchant may include a plasma-based etchant or a solvent-based etchant. The plasma-based etchant may be generated by a halogen-containing gas, such as a fluorine-containing gas, a chlorine-containing gas, a bromine-containing gas, other suitable gases, or combinations thereof, examples of which are describe herein with respect the etching processes E1 and E3.

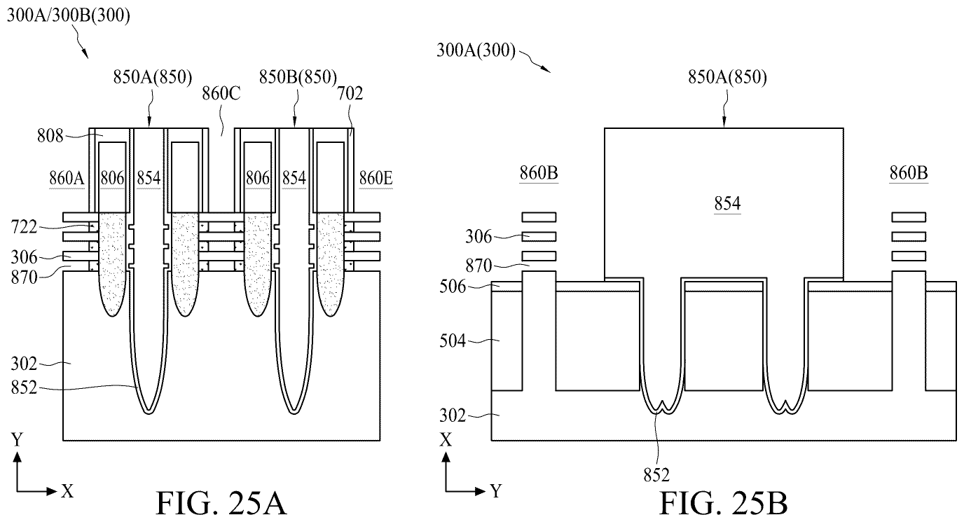

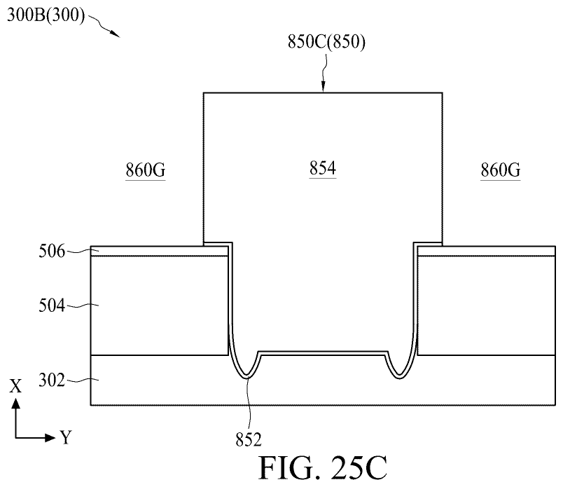

Referring to FIGS. 2A and 25A-25C, the remaining sacrificial layers 720 exposed by the gate trenches 860 are removed at the operation 222. In the present embodiments, removing the sacrificial layers 720 forms openings 870 each interposed between the inner spacers 722 (or 724) along the first lateral direction and interposed between the second semiconductor layer 306 along the vertical direction. In the present embodiments, the oxide layer 512 is also removed from the gate trenches 860 with the sacrificial layers 720.

The oxide layer 512 and the sacrificial layers 720 may be removed by performing an etching process similar to the second etching process E2 described herein. For example, the etching process may be implemented as a wet etching process using a wet etchant or a dry etching process using a plasma-based etchant. The wet etchant may include dHF, for example. In some embodiments, the dHF implemented at the operation 224 has a lower concentration than that implemented at the second etching process E2 to avoid or reduce etching of the inner spacers 722, which include an oxide as a major component. In some examples, the plasma-based etchant may include HF/NH₃ at a ratio different from that implemented at the second etching process E2.

In various embodiments, performing the etching process selectively removes the sacrificial layers 720, which include an oxide (e.g., silicon oxide) as a major component, to form the openings 870 below each corresponding gate trench 860. In some embodiments, after performing the etching process, the second semiconductor layers 306, the inner spacers 722 and 724, and the second spacer layer 702B of the gate spacers 702 remain substantially intact. In this regard, top and bottom surfaces of the second semiconductor layers 306 are exposed in the openings 870. For embodiments in which the first dielectric layer 852 includes silicon oxide, the etching process at the operation 224 may also remove vertical sidewalls of the first dielectric layer 852, thereby exposing the second dielectric layer 854 in the gate trenches 860, as depicted in FIGS. 25B and 25C.

Subsequently, referring to FIGS. 26A-27C, active gate structures 900 are formed in the gate trenches 860 and the openings 870 at the operation 224. In the present embodiments, top portions of the active gate structures 900A, 900B, 900C, 900D, and 900E are formed in the gate trenches 860A, 860B, 860C, 860D, and 860E, respectively, in the device 300A, and the active gate structures 900F, 900G, 900H, 900I, and 900J are formed in the gate trenches 860F, 860G, 860H, 860I, and 860J, respectively, in the device 300B. In addition, bottom portions of the active gate structures 900A-900J are formed in the openings 870 below the corresponding top portions and between the inner spacers 722 (or 724) such that each bottom portion wraps around the corresponding stack of second semiconductor layers 306. Stated differently, each bottom portion of the active gate structure 900 is interleaved with the second semiconductor layers 306. The active gate structures 900A-900J are collectively referred to as the active gate structures 900.

In the present embodiments, the active gate structures 900 each include at least a gate dielectric layer 902 and a gate metal 904 over the gate dielectric layer 902. The gate dielectric layer 902 may include any suitable dielectric material, such as a high-k dielectric material (e.g., a dielectric material having a dielectric constant greater than that of silicon oxide, which is about 3.9). Example high-k dielectric materials include a metal oxide or a metal silicate of Hf, Al, Zr, La, Mg, Ba, Ti, Pb, any other suitable materials, or combinations thereof. Additionally or alternatively, the gate dielectric layer 902 may include silicon oxide, silicon oxynitride, other suitable dielectric materials, or combinations thereof. The gate dielectric layer 902 may include a stack of multiple different dielectric materials.

As depicted in the cross-sectional view of FIG. 26C, the gate dielectric layer 902 extends along the gate spacers 702, over a bottom surface of the gate trench 860, and on exposed surfaces of the openings 870. As depicted in the top view of FIGS. 26A and 26B and the cross-sectional view of FIGS. 26D and 26E, the gate dielectric layer 902 of each of the active gate structures 900B, 900D, 900G, and 900I extends along sidewalls of the fin isolation structures 850A, 850B, 850C, and 850D, respectively, in the first lateral direction.

The gate metal 904 may include a stack of multiple metal materials. For example, the gate metal 904 may include at least a work function layer (not depicted separately) and a conductive fill layer (not depicted separately) disposed over the work function layer. The work function layer may include a p-type work function layer, an n-type work function layer, multilayers thereof, any other suitable materials, or combinations thereof. The work function layer may also be referred to as a work function metal. Example work function metals may include TiN, TaN, Ru, Mo, Al, WN, ZrSi₂, MoSi₂, TaSi₂, NiSi₂, Ti, Ag, TaAl, TaAlC, TiAlN, TaC, TaCN, TaSiN, Mn, Zr, other suitable materials, or combinations thereof. The conductive fill layer may include any suitable conductive material, such as polycrystalline silicon (polysilicon), tungsten (W), copper (Cu), cobalt (Co), ruthenium (Ru), aluminum (Al), titanium (Ti), tantalum (Ta), gold (Au), silver (Ag), platinum (Pt), other suitable conductive materials, or combinations (or alloys) thereof. The active gate structures 900 may further include additional layers, such as glue layers (or adhesive layers), capping layers, barrier layers, other suitable layers, or combinations thereof. In the depicted embodiments, the gate metal 904 fills each opening 870 between the second semiconductor layers 306 as well as each gate trench 860.

The gate dielectric layer 902 may be deposited by a conformal process, such as ALD, CVD, other suitable processes, or combinations thereof. Various layers of the gate metal 904 may each be deposited by any suitable method such as ALD, CVD, PVD, electroless plating, electroplating, other suitable methods, or combinations thereof. In some embodiments, portions of the gate dielectric layer 902 and the gate metal 904 are formed over top surfaces of the ILD layer 806 and the fin isolation structures 850, for example. Subsequently, the as-deposited gate dielectric layer 902 and the gate metal 904 are planarized using a suitable process, such as CMP, thereby exposing the top surfaces of the ILD layer 806 and the fin isolation structures 850, as depicted in FIGS. 26C-27C.

With respect to the device 300 illustrated in FIGS. 26A-26E, one of the source/drain features 802 adjacent to the fin isolation structure 850 is interposed between the lateral protrusions 856 (see FIG. 22C) and the inner spacers 722. In some embodiments, a sidewall of the source/drain feature 802 directly contacts the lateral protrusions 856 and the opposite sidewall of the source/drain feature 802 directly contacts the inner spacers 722. With respect to the device 300 illustrated in FIGS. 27A-27C, however, one of the source/drain features 802 adjacent to the fin isolation structure 850 is interposed between a first set of inner spacers 724 and a second set of the inner spacers 724 (see FIG. 23A). In some embodiments, a sidewall of the source/drain feature 802 directly contacts the first set of the inner spacers 724 and the opposite sidewall of the source/drain feature 802 directly contacts the second set of the inner spacers 724. Stated differently, for the device 300 that includes an oxide as a major component in the inner spacers (i.e., the inner spacers 722), at least portions of the inner spacers may be absent between the fin isolation structure 850 and the adjacent source/drain feature 802. For the device 300 that includes a nitride as a major component in the inner spacers (i.e., the inner spacers 724), the inner spacers are substantially intact and are interposed between the fin isolation structure 850 and the adjacent source/drain feature 802 along the first lateral direction.

As depicted in FIGS. 26C-27C collectively, the device 300 (300A or 300B) may optionally include the dielectric layer 804 formed below a bottom surface of the corresponding source/drain feature 802, as described in detail above with respect to FIG. 11C. Furthermore, the hard mask 506 may substantially remain over the top surfaces of the isolation structures 504 and below a bottommost surface of the active gate structures 900 and below a bottommost surface of the fin isolation structures 850.

Thereafter, referring to FIG. 2A, additional operations may be performed at the operation 226. For example, contact features (not depicted) may be formed to electrically couple components of the device 300, such as the active gate structures 900 and the source/drain features 802, with interconnect features formed over the device 300. The interconnect features may be formed in respective dielectric layers (e.g., intermetal dielectric layers) formed over the device 300, where the interconnect features may include a plurality of vertical interconnect features (e.g., vias) and horizontal interconnect features (e.g., conductive lines). The contact features and the interconnect features may include any suitable conductive materials, such as W, Cu, Co, Ru, Al, Ti, TiN, Ta, TaN, Au, Ag, Pt, other suitable materials, or combinations thereof. The dielectric layers may include any suitable materials similar to the component of the ILD layer 806.

FIGS. 28A-28B illustrate an embodiment of the device 300A in which the fin structures 400 are configured with the narrower fin width FW1, and FIGS. 29A-29B illustrate an embodiment of the device 300B in which the fin structures 400 are configured with the wider fin width FW2. In some embodiments, intentional misalignment of the patterned hard mask 730 is implemented to improve the formation of the fin isolation structures 850 when the device density (e.g., density of the fin structures 400 and/or the active gate structures 900) is increased at advanced technology nodes. In this regard, a width (e.g., width W4 and width W5 in FIGS. 28A/B and 29A/B, respectively) of the trench 842 (e.g., 842E and 842F in FIGS. 28A/B and 29A/B, respectively) is reduced due to a decreasing fin pitch (e.g., P1 and P2 of FIGS. 28A/B and 29A/B, respectively) between adjacent fin structures 400. The reduction in the width of the trench 842 may weaken the effect of the one or more of the etching processes (i.e., the second etching process E2 and the third etching process E3) implemented to form the fin cut trench 830 (e.g., 830E and 830F in FIGS. 28A/B and 29A/B, respectively).

For example, FIGS. 28A and 29A each illustrate the embodiment in which the patterned hard mask 370 is vertically centered with a center of the fin structure 400. As such, referring to FIG. 28A, the trench 842E forms a first opening 880 and a second opening 882 along each sidewall of the fin structure 400, respectively, where the first opening 880 and the second opening 882 have substantially the same width defined as (W4-FW1)/2. Similarly, referring to FIG. 29A, the trench 842F forms a first opening 890 and a second opening 892 along each sidewall of the fin structure 400, respectively, where the first opening 890 and the second opening 892 have substantially the same width defined as (W5-FW2)/2. In order for the etching processes E2 and E3 described herein to fully remove one or more of the oxide layer 512, the sacrificial layers 720, and the second semiconductor layer 306, etchants must be allowed to diffuse laterally across the trench 842. When the widths of the openings 880/882 and 890/892 are reduced due to the reduced widths W4 and W5, respectively, an amount of the etchant available for etching in the lateral (e.g., isotropic) direction in the trenches 842 may be limited or insufficient, causing incomplete removal of the sacrificial layers 720 and/or the second semiconductor layers 306, for example. This may in turn lead to structural defects in the subsequently formed fin isolation structures 850.

To improve the results of the etching processes, referring to FIG. 28B, the patterned hard mask 730 may be intentionally shifted (i.e., intentionally misalign the patterned mask 730 with the underlying dummy gate structures 600) to form a single opening 884 along one of the sidewalls of the fin structure 400 but not along the other one of the sidewalls. For example, after intentionally shifting the patterned hard mask 730, the trench 842E is no longer centered with the fin structure 400 but has a sidewall aligned with one of the sidewalls of the fin structure 400, leaving the opening 884 along the other one of the sidewalls of the fin structure 400. In some embodiments, a width of the opening 884 is defined as W4-FW1, which is larger than each of the widths of the openings 880 and 882 as described above. Similarly, referring to FIG. 29B, shifting the patterned hard mask 730 forms an opening 894 that has a width W5-FW2 that is greater than each of the widths of the openings 890 and 892 as described herein. Accordingly, the intentional pattern misalignment may help improve the removal of the sacrificial layers 720, for example, during the formation of the fin isolation structures 850 as described herein. In various embodiments, by implementing the multistep etching processes described herein, tolerance of any unintentional overlay shift along the first lateral direction can be greatly improved, thereby allowing any intentional misalignment of the fin isolation structures along the second lateral direction to be performed without causing any potential structural damage to the active components, such as the source/drain features, of the device.

In one aspect of the present disclosure, a method of fabricating a semiconductor device is disclosed. The method includes forming a fin protruding from a substrate, where the fin includes semiconductor layers interleaved with dielectric sacrificial layers. The method includes forming inner spacers at end portions of each of the dielectric sacrificial layers. The method includes forming source/drain features in the fin adjacent to the inner spacers. The method includes removing a portion of the fin between adjacent source/drain features to form a trench. The method includes forming an isolation structure in the trench.

In another aspect of the present disclosure, a method of fabricating a semiconductor device is disclosed. The method includes forming a multilayer structure over a substrate, where the multilayer structure includes first semiconductor layers interleaved with second semiconductor layers. The method includes forming a fin in the multilayer structure. The method includes forming a dummy gate structure over the fin. The method includes replacing the first semiconductor layers with sacrificial layers, where the sacrificial layers include a dielectric material. The method includes forming inner spacers at end portions of each of the sacrificial layers. The method includes forming source/drain features in the fin adjacent to the dummy gate structure. The method includes forming a fin isolation structure between adjacent source/drain features, where the fin isolation structure replaces a portion of the dummy gate structure and extending vertically into the substrate.

In yet another aspect of the present disclosure, a semiconductor device is disclosed. The semiconductor device includes a fin protruding from a substrate, the fin including a plurality of semiconductor layers. The semiconductor device includes an active gate structure including a lower portion interleaved with the semiconductor layers. The semiconductor device includes isolation structures over the substrate and surrounding the fin. The semiconductor device includes a hard mask interposed between a bottommost surface of the active gate structure and the isolation structures. The semiconductor device includes a source/drain feature disposed in the fin and adjacent to the active gate structure. The semiconductor device a fin isolation structure disposed in the fin adjacent to the source/drain feature, where the fin isolation structure extends parallel to the active gate structure, and where a bottom portion of the fin isolation structure extends into the substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a fin protruding from a substrate, the fin including semiconductor layers interleaved with dielectric sacrificial layers;
forming inner spacers at end portions of each of the dielectric sacrificial layers;
forming source/drain features in the fin adjacent to the inner spacers;
removing a portion of the fin between adjacent source/drain features to form a trench; and
forming an isolation structure in the trench.

2. The method of claim 1, where the inner spacers include an oxide material, and wherein removing the portion of the fin removes portions of the inner spacers.

3. The method of claim 1, wherein forming the fin includes:
forming a multilayer structure over the substrate, the multilayer structure including the semiconductor layers interleaved with semiconductor sacrificial layers,
patterning the multilayer structure to form the fin,
forming a dummy gate structure over the fin,
forming source/drain recesses in the fin adjacent to the dummy gate structure,
selectively remove the semiconductor sacrificial layers to form openings between the semiconductor layers in the fin, and
depositing an oxide material to fill the openings, thereby forming the dielectric sacrificial layers interleaved with the semiconductor layers in the fin.

4. The method of claim 1, wherein the trench is a first trench, and wherein the method further comprises:
forming a dummy gate structure over the fin before forming the inner spacers,
forming a patterned hard mask over the dummy gate structure to expose a portion of the dummy gate structure, and
removing the exposed portion of the dummy gate structure to form a second trench above and connected to the first trench such that the isolation structure is formed in the second trench.

5. The method of claim 1, wherein removing the portion of the fin includes:
performing a first etching process to selectively remove the dielectric sacrificial layers between the semiconductor layers in the fin; and
performing a second etching process to remove the remaining semiconductor layers.

6. The method of claim 5, wherein performing the second etching process further removes a portion of the substrate below the fin.

7. The method of claim 5, wherein performing the second etching process removes edge portions of the semiconductor layers at a first rate and removes a center portion of the semiconductor layers at a second rate that is less than the first rate.

8. The method of claim 5, wherein the first etching process is implemented as an isotropic wet etching process.

9. The method of claim 5, wherein the second etching process is implemented as a dry etching process.

10. A method, comprising:
forming a multilayer structure over a substrate, the multilayer structure including first semiconductor layers interleaved with second semiconductor layers;
forming a fin in the multilayer structure;
forming a dummy gate structure over the fin;
replacing the first semiconductor layers with sacrificial layers, the sacrificial layers including a dielectric material;
forming inner spacers at end portions of each of the sacrificial layers;
forming source/drain features in the fin adjacent to the dummy gate structure;
forming a fin cut trench between the source/drain features, wherein forming the fin cut trench includes selectively removing the sacrificial layers; and
forming a fin isolation structure in the fin cut trench, the fin isolation structure replacing a portion of the dummy gate structure and extending vertically into the substrate.

11. The method of claim 10, wherein replacing the first semiconductor layers includes:
forming source/drain recesses in the fin adjacent to the dummy gate structure,
selectively removing the first semiconductor layers to form openings between the second semiconductor layers in the fin, and
depositing an oxide material to fill the openings, thereby replacing the first semiconductor layers with the sacrificial layers.

12. The method of claim 10, wherein forming the fin cut trench further includes:
performing a first etching process to remove the dummy gate structure, resulting in a first trench,
performing a second etching process to selectively remove the sacrificial layers, resulting in openings between the second semiconductor layers, and
performing a third etching process to selectively remove the second semiconductor layers and a portion of the substrate, resulting in a second trench, wherein at least one sidewall of the second trench has a curved profile.

13. The method of claim 12, wherein the inner spacers include an oxide material, and wherein performing the second etching process removes the inner spacers.

14. The method of claim 12, wherein the inner spacers include a nitride material, and wherein performing the second etching process leaves at least a portion of the inner spacers intact.

15. A semiconductor structure, comprising:
a fin protruding from a substrate, the fin including a plurality of semiconductor layers;
an active gate structure including a lower portion interleaved with the semiconductor layers;
isolation structures over the substrate and surrounding the fin;
a hard mask interposed between a bottommost surface of the active gate structure and the isolation structures, the hard mask having a composition different from that of the isolation structures;
a source/drain feature disposed in the fin and adjacent to the active gate structure; and
a fin isolation structure disposed in the fin adjacent to the source/drain feature, the fin isolation structure extending parallel to the active gate structure, a bottom portion of the fin isolation structure extending into the substrate.

16. The semiconductor structure of claim 15, further comprising:
first inner spacers separating a sidewall of the fin isolation structure and a first sidewall of the first source/drain feature; and
second inner spacers separating a sidewall of the lower portion of the active gate structure and a second sidewall of the first source/drain feature opposite to the first sidewall.

17. The semiconductor structure of claim 16, wherein the first inner spacers and the second inner spacers each include a first amount of a nitride material and a second amount of an oxide material, the second amount being less than the first amount.

18. The semiconductor structure of claim 15, wherein:
a first sidewall of the fin isolation structure is in direct contact with a first sidewall of the first source/drain feature, and
the semiconductor structure further comprises inner spacers separating a second sidewall of the source/drain feature and a sidewall of the lower portion of the active gate structure, the second sidewall being opposite to the first sidewall.

19. The semiconductor structure of claim 18, wherein the inner spacers include a first amount of a nitride material and a second amount of an oxide material, the second amount being greater than the first amount.

20. The semiconductor structure of claim 15, wherein the bottom portion of the fin isolation structure include a first notch extending from a first sidewall of the fin isolation structure and a second notch extending from a second sidewall of the fin isolation structure opposite to the first sidewall.
